(19) United States
(12) Patent Application Publication
(10) Pub. No.: US 2026/0173874 A1
(43) Pub. Date: Jun. 18, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Eunho CHO, Suwon si (KR); YOUNG-DEUK KIM, Suwon si (KR); Junsoo KIM, Suwon-si (KR)

(21) Appl. No.: 19/293,373

(22) Filed: Aug. 7, 2025

(30) Foreign Application Priority Data
Dec. 13, 2024 (KR) 10-2024-0185938

(51) Int. Cl. H01L 23/373; H01L 23/00; H01L 25/065

(52) U.S. Cl. CPC H10W 40/254; H10W 90/00; H10W 72/01365; H10W 72/072; H10W 72/07232; H10W 72/073; H10W 72/07311; H10W 72/07332; H10W 72/241; H10W 72/327; H10W 72/337; H10W 72/348; H10W 72/353; H10W 72/354; H10W 72/357; H10W 72/365; H10W 72/367; H10W 72/387; H10W 74/15; H10W 90/288; H10W 90/297; H10W 90/722; H10W 90/732; H10W 99/00

(57) ABSTRACT

A semiconductor package includes a substrate including a plurality of vias passing therethrough, a chip stack mounted on the substrate, and a molding layer. The chip stack includes a first semiconductor chip, a second semiconductor chip, connection terminals electrically connecting the first semiconductor chip and the second semiconductor chip, and an adhesive layer between the first semiconductor chip and the second semiconductor chip and surrounding the connection terminals. The adhesive layer includes a thermal conductive layer in contact with the first semiconductor chip and the second semiconductor chip. The thermal conductive layer has a width that is greater than a height. A non-conductive layer surrounds the thermal conductive layer and the connection terminals. The thermal conductive layer is spaced apart from the connection terminals, and a thermal conductivity of the thermal conductive layer is greater than a thermal conductivity of the non-conductive layer.

### CROSS-REFERENCE TO RELATED APPLICATIONS

This U.S. non-provisional patent application claims priority under 35 U.S.C. § 119 to Korean Patent Application No. 10-2024-0185938 filed on Dec. 13, 2024, in the Korean Intellectual Property Office, the entire contents of which are hereby incorporated by reference.

### BACKGROUND OF THE INVENTION

The inventive concept relates to a semiconductor package and a method of manufacturing the same, and specifically relates to a stacked semiconductor package and a method of manufacturing the same.

With the development of the electronics industry, there is a growing demand for high functionality, high speed, and miniaturization of electronic components. To satisfy these demands, a packaging technique of providing a plurality of semiconductor chips in a single package has been suggested.

Recently, portable devices have been increasingly demanded in the electronics market, and thus small and light electronic components mounted in the electronics have been used. A semiconductor package technique of integrating a plurality of individual components in a single package as well as a technique of reducing a size of an individual component may be desirable to realize small and light electronic components. In particular, it may be beneficial for a semiconductor package in which a plurality of elements are integrated to have excellent bending characteristics, heat dissipation characteristics, and electrical characteristics as well as the reduced size. In this case, a plurality of adhesive materials are used to bond a plurality of elements to each other, and as the plurality of adhesive materials increases, various issues may occur.

In the semiconductor industry, integrated circuit packaging technology has been developed to satisfy requirements for miniaturization and high package reliability. For instance, packaging techniques capable of achieving a chip-size package are actively being developed to improve miniaturization, and packaging techniques capable of promoting efficiency in a packaging process and providing a high degree of mechanical and electrical reliability of a packaged product have attracted considerable attention.

### SUMMARY

An object of the inventive concept is to provide a semiconductor package with improved heat dissipation efficiency and a method of manufacturing the same.

According to some embodiments, a semiconductor package may include a substrate including a plurality of vias passing therethrough, a chip stack mounted on the substrate, and a molding layer surrounding the chip stack on the substrate. The chip stack includes a first semiconductor chip on the substrate, a second semiconductor chip on the first semiconductor chip, connection terminals between the first semiconductor chip and the second semiconductor chip and electrically connecting the first semiconductor chip and the second semiconductor chip, and an adhesive layer between the first semiconductor chip and the second semiconductor chip and surrounding the connection terminals. The adhesive layer includes a thermal conductive layer in contact with an upper surface of the first semiconductor chip and a lower surface of the second semiconductor chip. The thermal conductive layer comprises a width that is greater than a height of the thermal conductive layer. A non-conductive layer surrounds the thermal conductive layer and surrounds the connection terminals, wherein the thermal conductive layer is spaced apart from the connection terminals, and wherein a thermal conductivity of the thermal conductive layer is greater than a thermal conductivity of the non-conductive layer.

According to some embodiments, a semiconductor package may comprise an interposer substrate, and a chip stack on the interposer substrate. The chip stack includes a first semiconductor chip a second semiconductor chip on the first semiconductor chip, connection terminals between the first semiconductor chip and the second semiconductor chip and electrically connecting the first semiconductor chip and the second semiconductor chip, and a thermal conductive layer between the first semiconductor chip and the second semiconductor chip. The thermal conductive layer is horizontally spaced apart from the connection terminals, and wherein the thermal conductive layer includes carbon (C).

According to some embodiments, a method of manufacturing a semiconductor package may comprise providing a first semiconductor chip having a central region and an edge region surrounding the central region, the first semiconductor chip including chip pads on a first surface of the first semiconductor chip on the central region, electrically connecting connection terminals to the chip pads on the first surface of the first semiconductor chip, applying a non-conductive layer surrounding the connection terminals, performing a laser irradiation process on the non-conductive layer to form a thermal conductive layer, positioning a second semiconductor chip on the non-conductive layer and the thermal conductive layer, and performing a thermocompression process on the second semiconductor chip to bond the first semiconductor chip and the second semiconductor chip, wherein the thermal conductive layer includes laser induced graphene (LIG).

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a cross-sectional view illustrating a semiconductor package according to embodiments of the inventive concept.

FIG. 2 is a plan view illustrating a semiconductor package according to embodiments of the inventive concept.

FIG. 3 is an enlarged view of portion ‘B’ of FIG. 1.

FIG. 4 is a plan view illustrating a semiconductor package according to embodiments of the inventive concept.

FIGS. 5 to 7 are cross-sectional views illustrating a semiconductor package according to embodiments of the inventive concept.

FIGS. 8 and 9 are cross-sectional views illustrating a semiconductor package according to embodiments of the inventive concept.

FIG. 10 is a cross-sectional view illustrating a semiconductor package according to embodiments of the inventive concept.

FIG. 11 is a plan view illustrating a semiconductor package according to embodiments of the inventive concept.

FIGS. 12 and 13 are cross-sectional views illustrating a semiconductor package according to embodiments of the inventive concept.

FIG. 14 is a plan view illustrating a semiconductor package according to embodiments of the inventive concept.

FIG. 15 is a cross-sectional view illustrating a semiconductor package according to embodiments of the inventive concept.

FIG. 16 is a cross-sectional view illustrating a semiconductor module according to embodiments of the inventive concept.

FIGS. 17 to 24 are cross-sectional views illustrating a method of manufacturing a semiconductor package according to embodiments of the inventive concept.

### DETAILED DESCRIPTION

A semiconductor package according to the inventive concept is described with reference to the drawings.

As used herein, terms representing spatial relationships, such as “bottom,” “below,” “lower,” “top,” and “upper,” are intended only to describe relative positional relationships between elements or patterns shown in the drawings, and are used for ease of understanding only and do not limit the inventive concept at all. The terms for the relative positions in space are intended to encompass changes due to the orientation of a semiconductor package in addition to the directions shown in the drawings. That is, the semiconductor package may be oriented in various directions when used (or manufactured), and the terms for the positions used herein are easily understood by a person skilled in the art.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, components described as being “electrically connected” are configured such that an electrical signal can be transferred from one component to the other (although such electrical signal may be attenuated in strength as it is transferred and may be selectively transferred).

Various pads of a device described herein may be conductive terminals connected to internal wiring of the device, and may transmit signals and/or supply voltages between an internal wiring and/or internal circuit of the device and an external source. For example, chip pads of a semiconductor chip may electrically connect to and transmit supply voltages and/or signals between an integrated circuit of the semiconductor chip and a device to which the semiconductor chip is connected. The various pads may be on or near an external surface of the device and may have a planar surface having dimensions greater than wiring (e.g., X-Y horizontal dimensions of a pad are both greater than the width of an internal writing to which it is connected) to promote an electrical connection to a further terminal, such as a bump or solder ball, and/or an external wiring.

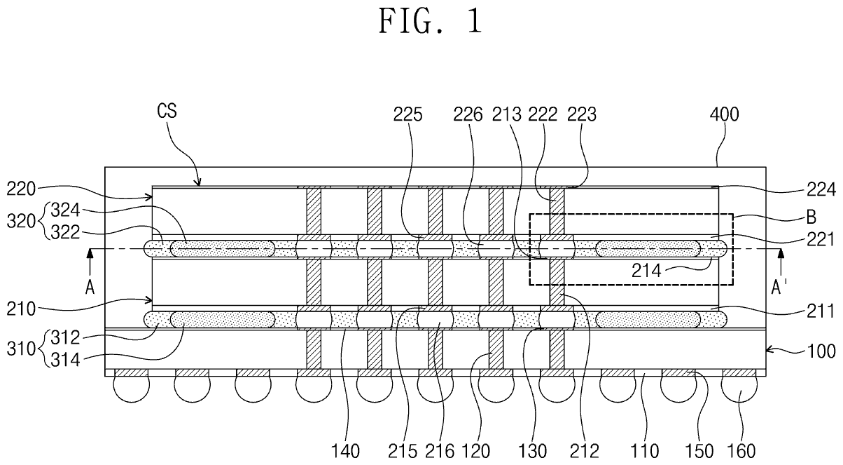

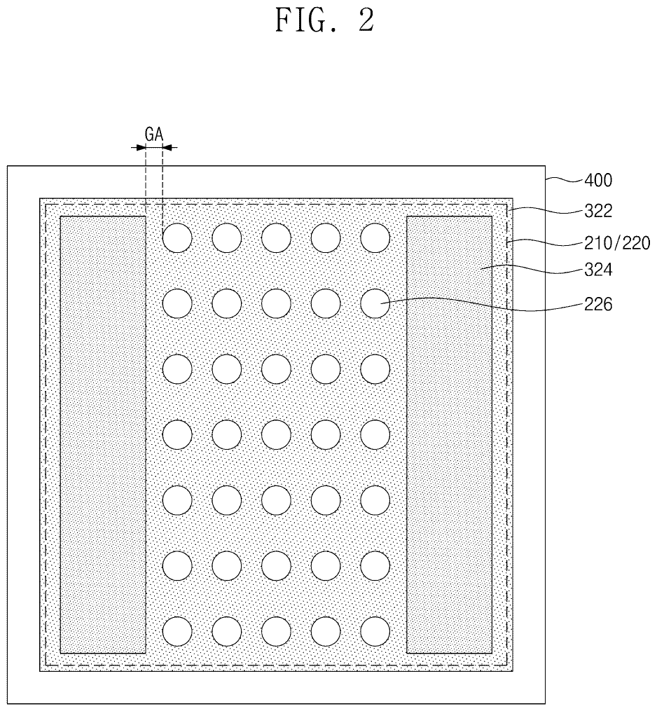

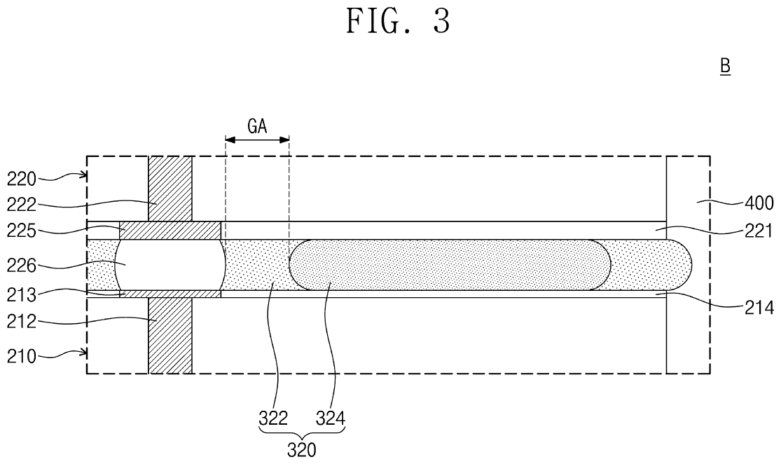

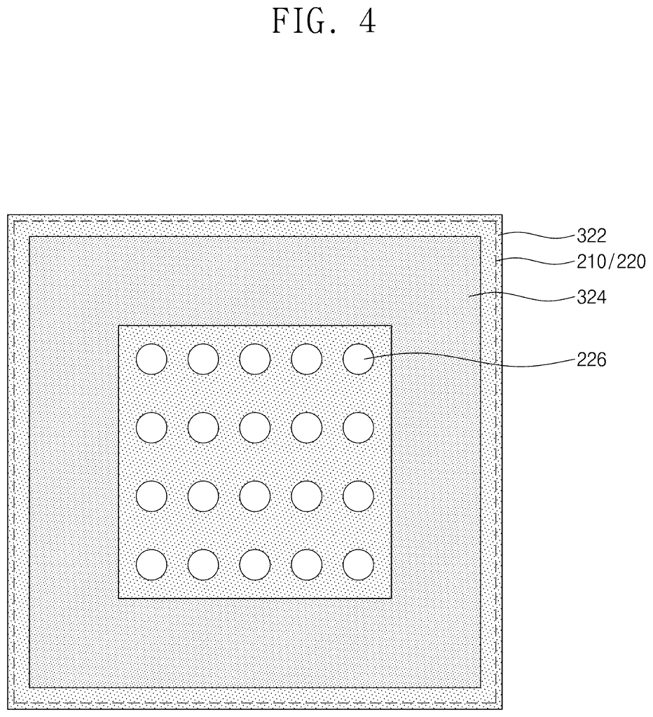

FIG. 1 is a cross-sectional view illustrating a semiconductor package according to embodiments of the inventive concept. FIG. 2 is a plan view illustrating a semiconductor package according to embodiments of the inventive concept. FIG. 3 is an enlarged view of portion ‘B’ of FIG. 1. FIG. 4 is a plan view illustrating a semiconductor package according to embodiments of the inventive concept. FIGS. 2 and 4 may correspond to a plan view along line A-A′ of FIG. 1.

Referring to FIGS. 1 to 3, a base substrate 100 may be provided. The base substrate 100 may include a direct circuit therein. The base substrate 100 may be a base semiconductor chip including an electronic element such as a transistor. For example, the base substrate 100 may be a die at a wafer level formed of a semiconductor such as silicon (Si). In FIG. 1, the base substrate 100 is illustrated as a base semiconductor chip, but, in other embodiments, the base substrate 100 may be a substrate that does not include certain electronic components (e.g., transistors, for example), and the base substrate 100 may be a printed circuit board (PCB). A silicon wafer may have a thickness that is less than a thickness of the printed circuit board (PCB). Hereinafter, the base substrate 100 and a base semiconductor chip 100 will be described as the same components.

The base semiconductor chip 100 may include a first circuit layer 110, a first via 120 that is part of a set or group of vias, a first backside pad 130 that is part of a set or group of backside pads, a first protective layer 140, and a first frontside pad 150 that is part of a set or group of frontside pads.

The first circuit layer 110 may be provided on a lower surface of the base semiconductor chip 100. The first circuit layer 110 may include the above-described integrated circuit. For example, the first circuit layer 110 may be a memory circuit, a logic circuit, or a combination thereof. That is, the lower surface of the base semiconductor chip 100 may be an active surface. The first circuit layer 110 may include electronic elements such as transistors, insulating patterns, and wiring patterns.

The first via 120 may vertically penetrate, and pass through, the base semiconductor chip 100. The first vias 120, and other vias disclosed herein, may comprise conductive through vias. For example, the first via 120 may electrically connect an upper surface of the base semiconductor chip 100 and the first circuit layer 110. The first via 120 and the first circuit layer 110 may be electrically connected. While only the first via 120 is described herein, other vias may be provided and may vertically penetrate the base semiconductor chip 100, such that the other vias may be similar in function and structure to the first via 120. In some embodiments, an insulating layer (not shown) surrounding the first via 120 may be provided. For example, the insulating layer (not shown) may include at least one of silicon oxide (SiO), silicon nitride (SiN), silicon oxynitride (SiON), or a low-k dielectric layer.

The first backside pad 130 may be disposed on an upper surface of the base semiconductor chip 100. The first backside pad 130 may be electrically connected to the first via 120. While only the first backside pad 130 is described herein, other backside pads may be provided and may be electrically connected to other vias, and the other backside pads may be similar in structure and function to the first backside pad 130. For example, each backside pad of the first backside pads 130 may be electrically connected to a via of the plurality of vias (e.g., that are each similar to the first via 120), and an arrangement of the first backside pads 130 may correspond to, when viewed from top-down plan view, an arrangement of the first vias 120. The first backside pad 130 may be electrically connected to the first circuit layer 110 through the first via 120. The first backside pad 130 may include various metal materials such as copper (Cu), aluminum (Al), and/or nickel (Ni).

The first protective layer 140 may be disposed on the upper surface of the base semiconductor chip 100 to surround the first backside pad 130 and the other backside pads. The first protective layer 140 may expose the first backside pad 130 and the other backside pads. An upper surface of the first protective layer 140 may be coplanar with an upper surface of the first backside pad 130 and the other backside pads. The base semiconductor chip 100 may be protected by the first protective layer 140. The first protective layer 140 may include silicon oxide (SiO), silicon nitride (SiN), silicon oxynitride (SiON), or silicon carbonitride (SiCN).

The first frontside pad 150 may be disposed on the lower surface of the base semiconductor chip 100. In detail, the first frontside pad 150 may be exposed at a lower surface of the first circuit layer 110, for example, with a lower surface of the first frontside pad 150 not covered by the first circuit layer 110. A lower surface of the first frontside pad 150 may be coplanar with the lower surface of the first circuit layer 110. The first frontside pad 150 may be electrically connected to the first circuit layer 110. While only the first frontside pad 150 is described herein, other frontside pads may be provided and may be similar in structure and function to the first frontside pad 150. The first frontside pad 150 may include various metal materials such as copper (Cu), aluminum (Al), and/or nickel (Ni).

Although not illustrated, the base semiconductor chip 100 may further include a lower protective layer (not illustrated). The lower protective layer (not shown) may be disposed on the lower surface of the base semiconductor chip 100 to cover the first circuit layer 110. The first circuit layer 110 may be protected by the lower protective layer. The lower protective layer may expose the first frontside pad 150. The lower protective layer may include silicon oxide (SiO), silicon nitride (SiN), silicon oxynitride (SiON), or silicon carbon nitride (SiCN).

An external terminal 160 may be provided on the lower surface of the base semiconductor chip 100. The external terminal 160 may be disposed on the first frontside pad 150. The external terminal 160 may be electrically connected to the first circuit layer 110 and the first via 120. Alternatively, the external terminal 160 may be disposed below the first via 120. In this case, the first via 120 may penetrate the first circuit layer 110 and be exposed on the lower surface of the first circuit layer 110, and the external terminal 160 may be directly connected to the first via 120. While only one external terminal 160 is described herein, other external terminals may be provided, and the other external terminals may be similar in structure and function to the external terminal 160. For example, each external terminal of the plurality of external terminals may be electrically connected to a frontside pad of the plurality of first frontside pads 150. The external terminal 160 may be an alloy including at least one of tin (Sn), silver (Ag), copper (Cu), nickel (Ni), bismuth (Bi), indium (In), antimony (Sb), or cerium (Ce).

A chip stack CS may be disposed on the base semiconductor chip 100. The chip stack CS may include a plurality of semiconductor chips, for example, a lower semiconductor chip 210 and an upper semiconductor chip 220. While FIG. 1 illustrates the chip stack CS as comprising two semiconductor chips 210, 220, the chip stack CS may comprise additional semiconductor chips that may be similar or identical to the illustrated semiconductor chips 210, 220, and layers between these additional, non-illustrated semiconductor chips may be similar or identical to the layers between the illustrated semiconductor chips 210, 220. The semiconductor chips 210 and 220 may be semiconductor chips of the same type. For example, the semiconductor chips 210 and 220 may be memory chips. The chip stack CS may include a lower semiconductor chip 210 directly connected to the base semiconductor chip 100, and an upper semiconductor chip 220 disposed on the lower semiconductor chip 210. The lower semiconductor chip 210 and the upper semiconductor chip 220 may be sequentially stacked on the base semiconductor chip 100. A width of the lower semiconductor chip 210 may be less than a width of the base semiconductor chip 100, and a width of the upper semiconductor chip 220 may be less than a width of the base semiconductor chip 100.

The lower semiconductor chip 210 may include a second circuit layer 211 facing the base semiconductor chip 100. The second circuit layer 211 may be provided on a lower surface of the lower semiconductor chip 210. The second circuit layer 211 may include the above-described integrated circuit. For example, the second circuit layer 211 may include a memory circuit. That is, the lower surface of the lower semiconductor chip 210 may be an active surface.

The second circuit layer 211 may include electronic elements such as transistors, an insulating pattern, and a wiring pattern. The lower semiconductor chip 210 may include a second protective layer 214 provided on an upper surface of the lower semiconductor chip 210. The second protective layer 214 may protect the lower semiconductor chip 210. The second protective layer 214 may include silicon oxide (SiO), silicon nitride (SiN), silicon oxynitride (SiON), or silicon carbonitride (SiCN).

The lower semiconductor chip 210 may include a second via 212 penetrating a portion of the lower semiconductor chip 210 in a vertical direction from the second protective layer 214 toward the second circuit layer 211. While only the second via 212 is described herein, other vias may be provided and may penetrate the lower semiconductor chip 210, with the other vias similar in structure and function to the second via 212. An insulating layer (not shown) may be provided to surround the second vias 212. For example, the insulating layer (not shown) may include at least one of silicon oxide (SiO), silicon nitride (SiN), silicon oxynitride (SiON), or a low-k dielectric layer. The second via 212, and the other vias penetrating the lower semiconductor chip 210, may be electrically connected to the second circuit layer 211.

A second backside pad 213 may be disposed in the second protective layer 214. The second backside pad 213 may have an upper surface thereof exposed by an opening in the second protective layer 214. An upper surface of the second protective layer 214 may be coplanar with an upper surface of the second backside pad 213. The second backside pad 213 may be electrically connected to the second via 212. A second frontside pad 215 may be disposed on the second circuit layer 211. In detail, the second frontside pad 215 may be exposed on the lower surface of the second circuit layer 211, for example, with an opening in the second circuit layer 211 exposing the second frontside pad 215. While only the second frontside pad 215 is described herein, other frontside pads may be provided and may be similar in structure and function to the second frontside pad 215. A lower surface of the second frontside pad 215 may be coplanar with the lower surface of the second circuit layer 211. According to other embodiments, the second backside pad 213 may contact the upper surface of the second protective layer 214 and/or an upper surface of the second backside pad 213 may be co-planar with the upper surface of the second protective layer 214, and the second frontside pad 215 may contact the lower surface of the second circuit layer 211 and/or a lower surface of the second frontside pad 215 may be co-planar with the lower surface of the second circuit layer 211.

Hereinafter, the description will continue based on the embodiment of FIG. 1. The second frontside pad 215 may be electrically connected to the second circuit layer 211. The second backside pad 213 may be electrically connected to the second frontside pad 215 by the second via 212 such that the second backside pad 213 (e.g., along with the second via 212 and the second frontside pad 215) may be electrically connected to the second circuit layer 211. While this discussion is related to the second backside pad 213 and the second frontside pad 215, additional backside pads (e.g., identical to the second backside pad 213) and additional frontside pads (e.g., identical to the second frontside pad 215) may be provided. The second backside pad 213 and the second frontside pad 215 may include various metal materials such as copper (Cu), aluminum (Al), and/or nickel (Ni).

The lower semiconductor chip 210 may be mounted on the base semiconductor chip 100, for example, by being disposed on the base semiconductor chip 100. The lower semiconductor chip 210 may be disposed on the base semiconductor chip 100 in a face down manner, for example, with the second circuit layer 211 of the lower semiconductor chip 210 facing the base semiconductor chip 100. The first backside pad 130 of the base semiconductor chip 100 and the second frontside pad 215 of the lower semiconductor chip 210 may be vertically aligned. Likewise, other backside pads of the base semiconductor chip 100 may be vertically aligned with other second frontside pads of the lower semiconductor chip 210, for example, with one backside pad vertically aligned with one frontside pad.

The lower semiconductor chip 210 may be electrically connected to the base semiconductor chip 100 by a first chip connection terminal 216. The first chip connection terminal 216 may be disposed between the first backside pad 130 of the base semiconductor chip 100 and the second frontside pad 215 of the lower semiconductor chip 210. The base semiconductor chip 100 and the lower semiconductor chip 210 may be spaced apart from each other in a vertical direction, and the first chip connection terminal 216 may have the same thickness (e.g., in the vertical direction) as a distance between the first backside pad 130 and the second frontside pad 215. While only one chip connection terminal (e.g., the first chip connection terminal 216) is described herein, other chip connection terminals may be provided, and the other chip connection terminals may be similar in structure and function to the first chip connection terminal 216. The first chip connection terminal 216 may electrically connect the base semiconductor chip 100 and the lower semiconductor chip 210. The first chip connection terminal 216 may be a solder ball or solder bump including an alloy including at least one of tin (Sn), silver (Ag), copper (Cu), nickel (Ni), bismuth (Bi), indium (In), antimony (Sb), or cerium (Ce).

The upper semiconductor chip 220 may have the same or similar configuration as the lower semiconductor chip 210.

The upper semiconductor chip 220 may include a third circuit layer 221 provided on a lower surface of the upper semiconductor chip 220 facing the lower semiconductor chip 210. The third circuit layer 221 may include the above-described integrated circuit. For example, the third circuit layer 221 may include a memory circuit. That is, the lower surface of the upper semiconductor chip 220 may be an active surface. The third circuit layer 221 may include electronic elements such as transistors, an insulating pattern, and a wiring pattern.

The upper semiconductor chip 220 may include a third protective layer 224 provided on an upper surface of the upper semiconductor chip 220. The third protective layer 224 may protect the upper semiconductor chip 220. The third protective layer 224 may include silicon oxide (SiO), silicon nitride (SiN), silicon oxynitride (SiON), or silicon carbon nitride (SiCN).

The upper semiconductor chip 220 may include a third via 222 vertically penetrating a portion of the upper semiconductor chip 220 in a direction from the third circuit layer 221 to the third protective layer 224. While only the third via 222 is described herein, other vias may be provided and may vertically penetrate the upper semiconductor chip 220, such that the other vias may be similar in function and structure to the third via 222. An insulating layer (not shown) may be provided to surround the third via 222. For example, the insulating layer may include at least one of silicon oxide (SiO), silicon nitride (SiN), silicon oxynitride (SiON), or a low-k dielectric layer. The third via 222 may be electrically connected to the third circuit layer 221.

A third backside pad 223 may be disposed in the third protective layer 224. An upper surface of the third backside pad 223 may be exposed by an opening in the third protective layer 224. An upper surface of the third protective layer 224 may be coplanar with the upper surface of the third backside pad 223. The third backside pad 223 may be electrically connected to the third via 222. A third frontside pad 225 may be disposed on or in the third circuit layer 221. In detail, the third frontside pad 225 may be exposed at a lower surface of the third circuit layer 221, for example, with a lower surface of the third frontside pad 225 not covered by the third circuit layer 221. A lower surface of the third frontside pad 225 may be coplanar with the lower surface of the third circuit layer 221. According to other embodiments, the third backside pad 223 may contact the upper surface of the third protective layer 224, and the third frontside pad 225 may contact the lower surface of the third circuit layer 221. Hereinafter, the description will continue based on the embodiment of FIG. 1. The third frontside pad 225 may be electrically connected to the third circuit layer 221. The third backside pad 223 may be electrically connected to the third frontside pad 225 by the third via 222 such that third backside pad 223 (e.g., along with the third via 222 and the third frontside pad 225) may be electrically connected to the third circuit layer 221. While this discussion is related to the third backside pad 223 and the third frontside pad 225, additional backside pads (e.g., identical to the third backside pad 223) and additional frontside pads (e.g., identical to the third frontside pad 225) may be provided. The third backside pad 223 and the third frontside pad 225 may include various metal materials such as copper (Cu), aluminum (Al), and/or nickel (Ni).

The upper semiconductor chip 220 may be mounted on the lower semiconductor chip 210, for example, by being disposed on the lower semiconductor chip 210. A size of the upper semiconductor chip 220 may be the same as, or similar to, a size of the lower semiconductor chip 210. For example, a width of the upper semiconductor chip 220 may be the same as or similar to a width of the lower semiconductor chip 210. Side surfaces of the upper semiconductor chip 220 may be vertically aligned with side surfaces of the lower semiconductor chip 210, for example, with a side surface of the upper semiconductor chip 220 being co-planar with a side surface of the lower semiconductor chip 210. The upper semiconductor chip 220 may be disposed on the lower semiconductor chip 210 in a face down manner, for example, with the third circuit layer 221 of the upper semiconductor chip 220 facing the lower semiconductor chip 210. The second backside pad 213 of the lower semiconductor chip 210 and the third frontside pad 225 of the upper semiconductor chip 220 may be vertically aligned. Likewise, other second backside pads of the lower semiconductor chip 210 may be vertically aligned with other third frontside pads of the upper semiconductor chip 220, for example, with one backside pad vertically aligned with one frontside pad.

The upper semiconductor chip 220 may be electrically connected to the lower semiconductor chip 210 by a second chip connection terminal 226. The second chip connection terminal 226 may be disposed between the second backside pad 213 of the lower semiconductor chip 210 and the third frontside pad 225 of the upper semiconductor chip 220. The lower semiconductor chip 210 and the upper semiconductor chip 220 may be spaced apart from each other in a vertical direction, and the second chip connection terminal 226 may have the same thickness (e.g., in the vertical direction) as a distance between the second backside pad 213 and the third frontside pad 225. While only one chip connection terminal (e.g., the second chip connection terminal 226) is described herein, other chip connection terminals may be provided, and the other chip connection terminals may be similar in structure and function to the second chip connection terminal 226. The second chip connection terminal 226 may electrically connect the lower semiconductor chip 210 and the upper semiconductor chip 220. The second chip connection terminal 226 may be a solder ball or solder bump including an alloy including at least one of tin (Sn), silver (Ag), copper (Cu), nickel (Ni), bismuth (Bi), indium (In), antimony (Sb), or cerium (Ce).

While the upper semiconductor chip 220 is illustrated in FIG. 1 as comprising a plurality of vias (e.g., including the third via 222), a plurality of backside pads (e.g., including the third backside pad 223), and the third protective layer 224, in some embodiments, the upper semiconductor chip 220 may include fewer vias than as illustrated and/or fewer backside pads than as illustrated, and in some embodiments, the upper semiconductor chip 220 may not include the third protective layer 224.

According to other embodiments, the upper semiconductor chip 220 may be disposed on the lower semiconductor chip 210 in a face up manner, for example, with the third backside pad 223 at a lower surface of the upper semiconductor chip 220 and the third frontside pad 225 at an upper surface of the upper semiconductor chip 220. In this case, the second chip connection terminals 226 may electrically connect the second backside pad 213 of the lower semiconductor chip 210 and the third backside pad 223 of the upper semiconductor chip 220. Hereinafter, the description will continue based on the embodiment of FIG. 1.

A second adhesive layer 320 may be provided between the upper semiconductor chip 220 and the lower semiconductor chip 210 in a vertical direction. The second adhesive layer 320 may fill a space between the upper semiconductor chip 220 and the lower semiconductor chip 210 and may surround the plurality of second chip connection terminals 226. The second adhesive layer 320 may protrude outwardly past the side surfaces of the lower semiconductor chip 210 and the side surfaces of the upper semiconductor chip 220. For example, as illustrated in FIG. 1, a side surface of the lower semiconductor chip 210 is co-planar with a side surface of the upper semiconductor chip 220, with the side surfaces (e.g., of the lower semiconductor chip 210 and the upper semiconductor chip 220) lying within a plane. By protruding outwardly past the side surfaces, the second adhesive layer 320 may pass through the plane (e.g., within which the side surfaces lie) such that a first portion of the second adhesive layer 320 is on one side of the plane, and a second portion of the second adhesive layer 320 is on an opposing side of the plane. In embodiments in which the side surfaces (e.g., of the lower semiconductor chip 210 and the upper semiconductor chip 220) do not lie within the same plane, a side surface of the lower semiconductor chip 210 may lie within a first plane, and a side surface of the upper semiconductor chip 220 may lie within a second plane, and the second adhesive layer 320 may pass through either or both of the first plane and the second plane to protrude outwardly.

The second adhesive layer 320 may include a second non-conductive layer 322 and a second thermal conductive layer 324. The second thermal conductive layer 324 may be disposed vertically between the upper semiconductor chip 220 and the lower semiconductor chip 210. The second thermal conductive layer 324 may be in contact with the upper surface of the lower semiconductor chip 210 (e.g., in contact with the second protective layer 214 of the lower semiconductor chip 210) and the lower surface of the upper semiconductor chip 220 (e.g., in contact with the third circuit layer 221 of the upper semiconductor chip 220). The second thermal conductive layer 324 may be horizontally spaced from the second chip connection terminals 226. For example, as illustrated in FIGS. 1-2, the second chip connection terminals 226 may be disposed on a central region of the lower semiconductor chip 210 and below a central region of the upper semiconductor chip 220. As illustrated in FIG. 2, the central region may be located toward a center of the semiconductor package relative to a horizontal direction. The central region may be spaced apart from edges or side surfaces of the lower semiconductor chip 210 and the upper semiconductor chip 220 along a line or axis that passes through a row of second chip connection terminals 226, wherein FIG. 2 illustrates five chip connection terminals 226 in each row. The semiconductor package is not limited to comprising five chip connection terminals 226 in each row and, instead, may comprise any number (e.g., one or more) of connection terminals 226 in a row, such that the five chip connection terminals 226 are illustrated for convenience. The second thermal conductive layer 324 may be disposed on an edge region of the lower semiconductor chip 210 and below an edge region of the upper semiconductor chip 220. In some embodiments, the edge region of the lower semiconductor chip 210 may be a region between the central region of the lower semiconductor chip 210 and one of side surfaces of the lower semiconductor chip 210. That is, the second thermal conductive layer 324 may be disposed between the central region of the lower semiconductor chip 210 and one of the side surfaces of the lower semiconductor chip 210, for example, between the second chip connection terminals 226 and one of the side surfaces of the lower semiconductor chip 210. The second thermal conductive layer 324 may be spaced apart from the side surfaces of the lower semiconductor chip 210 and the side surfaces of the upper semiconductor chip 220. The second thermal conductive layer 324 may be spaced a distance GA apart from an adjacent second chip connection terminal 226 among the second chip connection terminals 226, and the distance GA may be within a range from 1 micrometer to 20 micrometers. The second thermal conductive layer 324 may have upper surfaces and lower surfaces that are flat, and the second thermal conductive layer 324 may comprise a quadrilateral shape when viewed from above in a plan view. The second thermal conductive layer 324 may extend along one of the side surfaces of the lower semiconductor chip 210. For example, the second thermal conductive layer 324 may be a rectangular shape extending along one of the side surfaces of the lower semiconductor chip 210, when viewed in a plan view. As illustrated in FIG. 3, the second thermal conductive layer 324 may have convex side surfaces at an inner side and/or at an outer sider of the second thermal conductive layer 324.

As illustrated in FIG. 3, a distance may separate the connection terminal 226 from the edge (e.g., at the side surface) of the lower semiconductor chip 210, wherein the distance is measured in a horizontal direction parallel to an upper surface of the lower semiconductor chip 210 and between the connection terminal 226 and a nearest edge. In some embodiments, the thermal conductive layer 324 may be positioned in the area between the connection terminal 226 and the nearest edge (e.g., at the side surface) of the lower semiconductor chip 210. The thermal conductive layer 324 may comprise a width measured in the horizontal direction parallel to the upper surface of the lower semiconductor chip 210. In some embodiments, the width of the thermal conductive layer 324 may be greater than 25% of the distance separating the connection terminal 226 from the edge, or the width of the thermal conductive layer 324 may be greater than 50% of the distance separating the connection terminal 226 from the edge. As illustrated in FIG. 1, the width of the thermal conductive layer 324 in the horizontal direction may be greater than a height (e.g., or thickness) in the vertical direction of the thermal conductive layer 324, for example, with the width being at least 1.5 times the height, or the width being at least 2 times the height, or the width being at least 2.5 times the height, or the width being at least 3 times the height. By providing the thermal conductive layer 324 (e.g., and other thermal conductive layers) with these dimensions, the thermal conductive layer 324 (e.g., and other thermal conductive layers) may improve the heat dissipation within the semiconductor package.

According to embodiments, while the second thermal conductive layer 324 is described as being a single thermal conductive layer, the second thermal conductive layer 324 may be one of multiple thermal conductive layers. For example, as illustrated in FIG. 2, the second thermal conductive layers 324 may be disposed between the second chip connection terminals 226 and one of the side surfaces of the lower semiconductor chip 210, while another thermal conductive layer that is similar or identical to the second thermal conductive layer 324 may be disposed on an opposite side of the second chip connection terminals 226, for example, between the second chip connection terminals 226 and an opposing side surface of the lower semiconductor chip 210. Accordingly, the second chip connection terminals 226 may be disposed between two thermal conductive layers 324. Each of the second thermal conductive layers 324 may have a flat plate shape or the same shape. Each of the second thermal conductive layers 324 may extend along one of the side surfaces of the lower semiconductor chip 210, for example, with one thermal conductive layer 324 extending along a first side surface of the lower semiconductor chip 210, and a second thermal conductive layer 324 extending along an opposing second side surface of the lower semiconductor chip 210, with the first side surface being parallel to the second side surface.

FIG. 2 illustrates two, separate, second thermal conductive layers 324, for example, with one thermal conductive layer 324 on a first side of the central region and a second thermal conductive layer 324 on an opposing second side of the central region, and the two thermal conductive layers 324 spaced apart and not in contact with one another. According to other embodiments, as illustrated in FIG. 4, the second thermal conductive layer 324 may be a ring shape extending along all of the side surfaces of the lower semiconductor chip 210, when viewed in a plan view. For example, the second thermal conductive layer 324 may be a square ring shape, when viewed in a plan view. As such, and as illustrated in FIG. 4, the second thermal conductive layer 324 may form a single, unitary structure that extends unbroken and continuously around the central region. However, the inventive concept is not limited thereto. According to other embodiments, the second thermal conductive layer 324 may have an ‘L’ shape extending along two of the side surfaces of the lower semiconductor chip 210, for example, with the thermal conductive layer 324 comprising a first segment extending along one side surface, and a second segment, extending along a second side surface, with the first segment and the second segment joined together and extending perpendicular to one another. Alternatively, the second thermal conductive layer 324 may have a ‘Π’ shape extending along three of the side surfaces of the lower semiconductor chip 210, when viewed in a plan view, for example, with the second thermal conductive layer 324 comprising a first segment extending along one side surface, a second segment extending along a second side surface, and a third segment extending along a third side surface, with the first segment, the second segment, and the third segment joined together. As such, the first segment and the third segment are parallel to each other, and the second segment joins the first segment and the second segment while extending perpendicular to the first segment and the second segment. Hereinafter, the description will continue based on the embodiment of FIG. 2.

The second thermal conductive layer 324 may include a material having high thermal conductivity. The second thermal conductive layer 324 may be made of carbon (C). As an example, the second thermal conductive layer 324 may include graphene. In some embodiments, the second thermal conductive layer 324 may include laser induced graphene (LIG). According to other embodiments, the second thermal conductive layer 324 may include diamond. According to other embodiments, the second thermal conductive layer 324 may include a metal material. The thermal conductivity of the second thermal conductive layer 324 may be greater than, or equal to, 40 watts per meter*kelvin (W/m*K), or may be greater than, or equal to, 65 W/m*K, or may be greater than, or equal to, 90 W/m*K. For example, when the second thermal conductive layer 324 comprises a thermal conductivity of 40 W/m*K, an operating thermal resistance of the semiconductor package may be 0.875° C./W, and when the second thermal conductive layer 324 comprises a thermal conductivity of 65 W/m*K, an operating thermal resistance of the semiconductor package may be 0.872° C./W, and when the second thermal conductive layer 324 comprises a thermal conductivity of 90 W/m*K, an operating thermal resistance of the semiconductor package may be 0.869° C./W. The operating thermal resistance is a quantification of the resistance to heat flow, and represents the temperature difference that is required to transfer one watt of heat through a material. As such, depending on the material and thermal conductivity of the second thermal conductive layer 324, the operating thermal resistance of semiconductor package may be less than 0.95, or less than 0.9, or less than 0.88, or less than 0.875, or less than 0.87, or within a range from 0.86 to 0.89. Here, the semiconductor package is assumed to have a structure in which 12 semiconductor chips are stacked on a base semiconductor chip 100 and an adhesive layer (same as the second adhesive layer 320) is provided between the semiconductor chips.

In some embodiments, a thermal conductivity of each of the thermal conductive layers disclosed herein may be constant throughout the respective thermal conductive layer. For example, with reference to the second thermal conductive layer 324, the thermal conductivity at a bottom of the second thermal conductive layer 324 may be substantially the same as the thermal conductivity at a center of the second thermal conductive layer 324 relative to the vertical direction. Likewise, the thermal conductivity at the bottom and the center may be substantially the same as the thermal conductivity at a top of the second thermal conductive layer 324 relative to the vertical direction. The bottom of the second thermal conductive layer 324 may be in contact with the second protective layer 214, and the top of the second thermal conductive layer 324 may be in contact with third circuit layer 221. As such, the second thermal conductive layer 324 may be a single, unitary body. A unitary body may be a monolithic or integrated structure that is formed continuously without a grain boundary therebetween, while a non-unitary structure may be formed of different materials with a grain boundary between the two different materials. In some embodiments, the height of the second thermal conductive layer 324 may be equal to a height of the second non-conductive layer 322 in the vertical direction. While this description of the thermal conductivity, shape, composition, etc. is directed toward the second non-conductive layer 322 and/or the second thermal conductive layer 324, the other non-conductive layers disclosed herein may comprise the same respective thermal conductivity characteristics, shapes, and compositions as the second non-conductive layer 322, and the other thermal layers disclosed herein may comprise the same respective thermal conductivity characteristics, shapes, and compositions as the second thermal conductive layer 324.

The second non-conductive layer 322 may be disposed between the upper semiconductor chip 220 and the lower semiconductor chip 210. The second non-conductive layer 322 may be in contact with an upper surface of the lower semiconductor chip 210 and a lower surface of the upper semiconductor chip 220. The second non-conductive layer 322 may fill a space vertically between the upper semiconductor chip 220 and the lower semiconductor chip 210. When viewed from above in a plan view, the second non-conductive layer 322 may surround the single, continuous, second thermal conductive layer 324 (e.g., as illustrated in FIG. 4) or may surround the plurality of second thermal conductive layers 324 (e.g., as illustrated in FIG. 2). Referring to FIG. 3 and focusing on the illustrated second thermal conductive layer 324 as an example, the second non-conductive layer 322 may be in contact with the second thermal conductive layer 324. For example, the second non-conductive layer 322 may be in contact with the side surfaces of the second thermal conductive layer 324. For example, the second non-conductive layer 322 may be in contact with an inner side surface of the second thermal conductive layer 324 that faces, and is nearer to, the second chip connection terminals 226, and the second non-conductive layer 322 may be in contact with an outer side surface of the second thermal conductive layer 324 that faces, and is nearer to, the edge region. The side surfaces of the second thermal conductive layer 324 may be convex and may extend outwardly toward the second non-conductive layer 322. When viewed in a plan view, the second non-conductive layer 322 may surround the second chip connection terminals 226. For example, focusing on one second chip connection terminal 226 in FIG. 3, the second non-conductive layer 322 may be in contact with the second chip connection terminal 226. For example, the second non-conductive layer 322 may be in contact with side surfaces of the second chip connection terminal 226. The second non-conductive layer 322 may fill a space between the second chip connection terminals 226 and the second thermal conductive layer 324. With the second non-conductive layer 322 surrounding the second chip connection terminals 226, the second thermal conductive layer 324 may be separated from the second chip connection terminals 226 and electrically insulated from the second chip connection terminals 226. The second non-conductive layer 322 may protrude outwardly past the side surfaces of the lower semiconductor chip 210 and the side surfaces of the upper semiconductor chip 220. For example, the second non-conductive layer 322 may have convex side surfaces that protrude outwardly and away from the second thermal conductive layer 324. That is, the side surfaces of the second non-conductive layer 322 may protrude toward a molding layer 400 described below.

The thermal conductivity of the second non-conductive layer 322 may be lower than a thermal conductivity of the second thermal conductive layer 324. For example, the thermal conductivity of the second non-conductive layer 322 may be less than 1 W/m*K. In some embodiments, the thermal conductivity of the second thermal conductive layer 324 may be at least 40 times greater than the thermal conductivity of the second non-conductive layer 322, or the thermal conductivity of the second thermal conductive layer 324 may be at least 65 times greater than the thermal conductivity of the second non-conductive layer 322, or the thermal conductivity of the second thermal conductive layer 324 may be at least 90 times greater than the thermal conductivity of the second non-conductive layer 322. The second non-conductive layer 322 may include a non-conductive film (NCF) or a non-conductive paste (NCP). The second non-conductive layer 322 may include an insulating polymer. In some embodiments, the insulating polymer may be a polymer having a carbon (C) element. For example, the second non-conductive layer 322 may be formed of an epoxy-based material that does not contain conductive particles. The second non-conductive layer 322 may include polyimide (PI) or polyethylene terephthalate (PET). By using the second non-conductive layer 322 without conductive particles, the second chip connection terminals 226 may be fine-pitched and positioned close together without electrical short-circuiting occurring between adjacent second chip connection terminals 226. In addition, the second non-conductive layer 322 may act as an underfill that fills a space between the lower semiconductor chip 210 and the upper semiconductor chip 220, thereby increasing mechanical durability of the second non-conductive layer 322.

According to other embodiments, the second thermal conductive layer 324 may further include an impurity therein. For example, the second thermal conductive layer 324 may include graphene, and the impurity may include at least one of the materials or elements constituting the second non-conductive layer 322. The impurity may be one of the materials or elements excluding carbon (C) among the elements constituting the second non-conductive layer 322 (e.g., polyimide (PI), polyethylene terephthalate (PET), etc.).

A first adhesive layer 310 may be provided between the lower semiconductor chip 210 and the base semiconductor chip 100 in a vertical direction. The first adhesive layer 310 may fill a space between the lower semiconductor chip 210 and the base semiconductor chip 100 and may surround the plurality of first chip connection terminals 216. The first adhesive layer 310 may protrude outwardly past the side surfaces of the lower semiconductor chip 210.

A configuration of the first adhesive layer 310 may be substantially the same as or similar to the configuration of the second adhesive layer 320. The first adhesive layer 310 may include a first non-conductive layer 312 and a first thermal conductive layer 314.

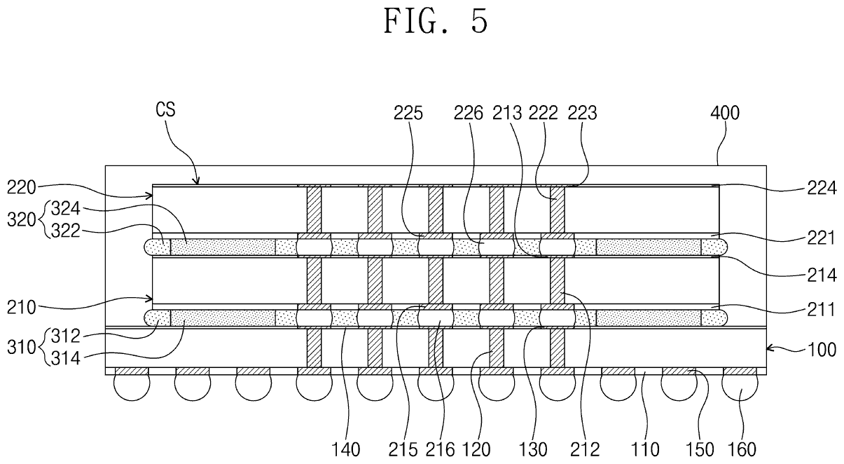

The materials, thermal conductivities, shapes, composition, etc. of the first non-conductive layer 312 and the first thermal conductive layer 314 may be the same as respective materials, thermal conductivities, shapes, composition, etc. of the second non-conductive layer 322 and the second thermal conductive layer 324. Likewise, the position of the first non-conductive layer 312 relative to the first thermal conductive layer 314 may be the same as the position of the second non-conductive layer 322 relative to the second thermal conductive layer 324. For example, the first thermal conductive layer 314 may be disposed between the lower semiconductor chip 210 and the base semiconductor chip 100. The first thermal conductive layer 314 may be in contact with the upper surface of the base semiconductor chip 100 (e.g., in contact with the first protective layer 140 of the base semiconductor chip 100) and the lower surface of the lower semiconductor chip 210 (e.g., in contact with the second circuit layer 211 of the lower semiconductor chip 210). The first thermal conductive layer 314 may be horizontally spaced apart from the first chip connection terminals 216. For example, the first chip connection terminals 216 may be disposed on a central region of the base semiconductor chip 100 and below the central region of the lower semiconductor chip 210. The first thermal conductive layer 314 may be positioned near the edge region of the lower semiconductor chip 210. That is, the first thermal conductive layer 314 may be disposed between the central region of the lower semiconductor chip 210 and one of side surfaces of the lower semiconductor chip 210, for example, between the first chip connection terminals 216 and one of the side surfaces of the lower semiconductor chip 210. The first thermal conductive layer 314 may be spaced apart from the side surfaces of the lower semiconductor chip 210. Similar to the second thermal conductive layer 324 illustrated in FIG. 2, the first thermal conductive layer 314 may be spaced the distance GA from the adjacent first chip connection terminals 216 among the first chip connection terminals 216, and the distance GA may be within a range from 1 micrometer to 20 micrometers. The first thermal conductive layer 314 may have upper surfaces and lower surfaces that are flat, and the first thermal conductive layer 314 may comprise a quadrilateral shape when viewed from above in a plan view. The first thermal conductive layer 314 may extend along one of the side surfaces of the lower semiconductor chip 210. For example, the first thermal conductive layer 314 may be a rectangular shape extending along any one of the side surfaces of the lower semiconductor chip 210, when viewed in a plan view. As illustrated in FIG. 5, the first thermal conductive layer 314 may have convex side surfaces at an inner side and/or at an outer side of the first thermal conductive layer 314.

According to embodiments, while the first thermal conductive layer 314 is described as being a single thermal conductive layer, the first thermal conductive layer 314 may be one of multiple thermal conductive layers. For example, the first thermal conductive layers 314 may be disposed between the first chip connection terminals 216 and one of the side surfaces of the lower semiconductor chip 210, while another thermal conductive layer that is identical to the first thermal conductive layer 314 may be disposed on an opposite side of the first chip connection terminals 216, for example, between the first chip connection terminals 216 and an opposing side surface of the lower semiconductor chip 210. Accordingly, the first chip connection terminals 216 may be disposed between the first thermal conductive layers 314. Each of the first thermal conductive layers 314 may have the same shape. Each of the first thermal conductive layers 314 may extend along one of the side surfaces of the lower semiconductor chip 210, for example, with one thermal conductive layer 314 extending along the first side surface of the lower semiconductor chip 210, and a second thermal conductive layer 314 extending along the opposing second side surface of the lower semiconductor chip 210, with the first side surface being parallel to the second side surface.

Similar to the second thermal conductive layers 324 illustrated in FIGS. 2 and 4, the first thermal conductive layer 314 can be formed as two separate thermal conductive layers (e.g., similar to the embodiment of FIG. 2). According to other embodiments, similar to the thermal conductive layer 324 of FIG. 4, the first thermal conductive layer 314 may be a ring shape extending along all of the side surfaces of the lower semiconductor chip 210 when viewed in a plan view. For example, the first thermal conductive layer 314 may be a square ring shape when viewed in a plan view. As such, and as illustrated in FIG. 4, the first thermal conductive layer 314 may form a single, unitary structure that extends unbroken and continuously around the central region. However, the inventive concept is not limited thereto. According to other embodiments, the first thermal conductive layer 314 may have an ‘L’ shape extending along two of the side surfaces of the lower semiconductor chip 210, for example, with the first thermal conductive layer 314 comprising a first segment extending along one side surface, and a second segment, extending along a second side surface, with the first segment and the second segment joined together and extending perpendicular to one another. Alternatively, the first thermal conductive layer 314 may have a ‘Π’ shape extending along three of the side surfaces of the lower semiconductor chip 210 when viewed in a plan view, for example, with the first thermal conductive layer 314 comprising a first segment extending along one side surface, a second segment extending along a second side surface, and a third segment extending along a third side surface, with the first segment, the second segment, and the third segment joined together. As such, the first segment and the third segment are parallel to each other, and the second segment joins the first segment and the second segment while extending perpendicular to the first segment and the second segment.

The first thermal conductive layer 314 may include a material having high thermal conductivity. The first thermal conductive layer 314 may be made of carbon (C). For example, the first thermal conductive layer 314 may include graphene. In some embodiments, the first thermal conductive layer 314 may include laser induced graphene (LIG). According to other embodiments, the first thermal conductive layer 314 may include diamond. According to other embodiments, the first thermal conductive layer 314 may include a metallic material. The thermal conductivity of the first thermal conductive layer 314 may be greater than, or equal to, 40 watts per meter*kelvin (W/m*K), or may be greater than, or equal to, 65 W/m*K, or may be greater than, or equal to, 90 W/m*K.

The first non-conductive layer 312 may be disposed between the lower semiconductor chip 210 and the base semiconductor chip 100. The first non-conductive layer 312 may be in contact with the upper surface of the base semiconductor chip 100 and the lower surface of the lower semiconductor chip 210. The first non-conductive layer 312 may fill a space vertically between the lower semiconductor chip 210 and the base semiconductor chip 100. When viewed from above in a plan view, the first non-conductive layer 312 may surround the first thermal conductive layer 314. The first non-conductive layer 312 may be in contact with the first thermal conductive layer 314. For example, the first non-conductive layer 312 may be in contact with the side surfaces of the first thermal conductive layer 314. For example, the first non-conductive layer 312 may be in contact with an inner side surface of the first thermal conductive layer 314 that faces, and is nearer to, the first chip connection terminals 216, and the first non-conductive layer 312 may be in contact with an outer side surface of the first thermal conductive layer 314 that faces, and is nearer to, the edge region. The side surfaces of the first thermal conductive layer 314 may be convex and may extend outwardly toward the first non-conductive layer 312. When viewed in a plan view, the first non-conductive layer 312 may surround the first chip connection terminals 216. The first non-conductive layer 312 may be in contact with the first chip connection terminals 216. For example, the first non-conductive layer 312 may be in contact with the side surfaces of the first chip connection terminals 216. The first non-conductive layer 312 may fill a space between the first chip connection terminals 216 and the first thermal conductive layer 314. With the first non-conductive layer 312 surrounding the first chip connection terminals 216, the first thermal conductive layer 314 may be separated from the first chip connection terminals 216 and electrically insulated from the first chip connection terminals 216. The first non-conductive layer 312 may protrude outwardly past the side surfaces of the lower semiconductor chip 210. For example, the first non-conductive layer 312 may have convex side surfaces that protrude outwardly and away from the first thermal conductive layer 314. That is, side surfaces of the first non-conductive layer 312 may protrude toward the molding layer 400 described below.

A thermal conductivity of the first non-conductive layer 312 may be lower than a thermal conductivity of the first thermal conductive layer 314. For example, the thermal conductivity of the first non-conductive layer 312 may be less than 1 W/m*K. In some embodiments, the thermal conductivity of the first non-conductive layer 312 may be at least 40 times greater than the thermal conductivity of the first non-conductive layer 312, or the thermal conductivity of the first thermal conductive layer 314 may be at least 65 times greater than the thermal conductivity of the first non-conductive layer 312, or the thermal conductivity of the first thermal conductive layer 314 may be at least 90 times greater than the thermal conductivity of the first non-conductive layer 312. The first non-conductive layer 312 may include a non-conductive film (NCF) or a non-conductive paste (NCP). The first non-conductive layer 312 may include an insulating polymer. In some embodiments, the insulating polymer may be a polymer having a carbon (C) element. For example, the first non-conductive layer 312 may be formed of an epoxy-based material that does not contain conductive particles. The first non-conductive layer 312 may include polyimide (PI) or polyethylene terephthalate (PET). By using the first non-conductive layer 312 without conductive particles, the first chip connection terminals 216 may be fine-pitched and positioned close together without electrical short-circuiting occurring between adjacent first chip connection terminals 216. In addition, the first non-conductive layer 312 may act as an underfill that fills a space between the lower semiconductor chip 210 and the base semiconductor chip 100, thereby increasing the mechanical durability of the first non-conductive layer 312.

According to other embodiments, the first thermal conductive layer 314 may further include an impurity therein. For example, the first thermal conductive layer 314 may include graphene, and the impurity may include at least one of the elements constituting the first non-conductive layer 312. The impurity may be one of the elements excluding carbon (C) among the elements constituting the first non-conductive layer 312 (e.g., polyimide (PI), polyethylene terephthalate (PET), etc.).

A molding layer 400 may be provided on the base semiconductor chip 100. The molding layer 400 may cover the upper surface of the base semiconductor chip 100. Side surfaces of the molding layer 400 may be aligned with side surfaces of the base semiconductor chip 100 such that side surfaces of the molding layer 400 may be co-planar with side surfaces of the base semiconductor chip 100. The molding layer 400 may surround the chip stack CS. That is, the molding layer 400 may cover the side surfaces of the lower semiconductor chip 210 and the side surfaces of the upper semiconductor chip 220. In some embodiments, the outer surface of the molding layer 400 may be spaced apart from the first adhesive layer 310 and the second adhesive layer 320, with the molding layer 400 surrounding outer edges of the adhesive layer 310 and the second adhesive layer 320. The molding layer 400 may be formed to cover the lower semiconductor chip 210 and the upper semiconductor chip 220. While the figures illustrate the molding layer 400 as covering and overlapping an upper surface of the upper semiconductor chip 200, in other embodiments, the molding layer 400 may expose the upper surface of the upper semiconductor chip 220 such that the molding layer 400 may not cover the upper surface of the upper semiconductor chip 200. The molding layer 400 may include an insulating material. For example, the molding layer 400 may include an epoxy molding compound (EMC).

According to embodiments, the first adhesive layer 310 provided between the base semiconductor chip 100 and the lower semiconductor chip 210 may include the first thermal conductive layer 314 having high thermal conductivity, and the second adhesive layer 320 provided between the lower semiconductor chip 210 and the upper semiconductor chip 220 may include the second thermal conductive layer 324 having high thermal conductivity. Accordingly, heat generated in the base semiconductor chip 100, the lower semiconductor chip 210, and the upper semiconductor chip 220 may be quickly transferred in the vertical direction, and the heat may be easily discharged to the outside of the semiconductor package. That is, a semiconductor package having high heat dissipation efficiency may be provided. In addition, the first thermal conductive layer 314 and the second thermal conductive layer 324 may be disposed spaced apart from the first chip connection terminals 216 and the second chip connection terminals 226, which reduces the likelihood of an electrical short occurring between the first chip connection terminals 216 or between the second chip connection terminals 226. Furthermore, the first non-conductive layer 312 may be provided between the base semiconductor chip 100 and the lower semiconductor chip 210, and the second non-conductive layer 322 may be provided between the lower semiconductor chip 210 and the upper semiconductor chip 220. The first non-conductive layer 312 surrounding the first thermal conductive layer 314 and the second non-conductive layer 322 surrounding the second thermal conductive layer 324 may bury the first thermal conductive layer 314 and the second thermal conductive layer 324, respectively. As such, the first thermal conductive layer 314 is positioned horizontally between the first non-conductive layer 312, and the second thermal conductive layer 324 is positioned horizontally between the second non-conductive layer 322. This positioning may limit the first thermal conductive layer 314 and the second thermal conductive layer 324 from moving to the outside of the lower semiconductor chip 210, thus maintaining a position of the first thermal conductive layer 314 and the second thermal conductive layer 324 between respective semiconductor chips. Furthermore, the first non-conductive layer 312 and the second non-conductive layer 322 may have a higher adhesive strength than an adhesive strength of the first thermal conductive layer 314 and the second thermal conductive layer 324. Therefore, the first non-conductive layer 312 may adhere the base semiconductor chip 100 to the lower semiconductor chip 210, and the second non-conductive layer 322 may adhere the lower semiconductor chip 210 to the upper semiconductor chip 220. Accordingly, a semiconductor package with improved structural stability is provided.

In the following embodiments, for the convenience of explanation, detailed descriptions of technical features that overlap with those described above with reference to FIGS. 1 to 4 will be omitted, and differences will be described in detail. The same reference numerals may be provided for the same configurations as the semiconductor package according to the embodiments of the inventive concept described above.

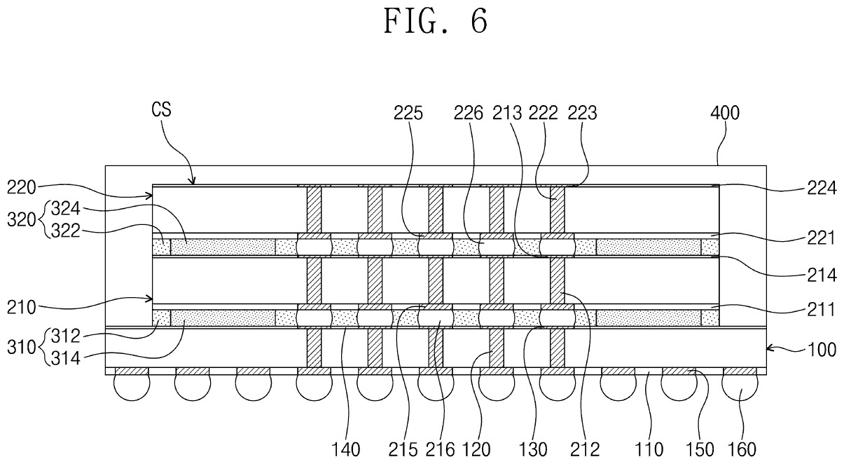

FIGS. 5 and 6 are cross-sectional views illustrating the semiconductor package according to the embodiments of the inventive concept.

Referring to FIG. 5, the second thermal conductive layer 324 may have flat side surfaces. For example, the side surfaces of the second thermal conductive layer 324 may be perpendicular to the upper surface of the lower semiconductor chip 210. A cross section of the second thermal conductive layer 324 may be rectangular. As such, an inner surface of the second thermal conductive layer 324 may be flat or planar, and an outer surface of the second thermal conductive layer 324 may also be flat or planar. Surfaces of the second non-conductive layer 322 that are in contact with the second thermal conductive layer 324 may be flat or planar to match the shape of side surfaces of the second thermal conductive layer 324.

A first thermal conductive layer 314 may have flat side surfaces. For example, the side surfaces of the first thermal conductive layer 314 may be perpendicular to the lower surface of the base semiconductor chip 100. A cross section of the first thermal conductive layer 314 may be rectangular. As such, an inner surface of the first thermal conductive layer 314 may be flat or planar, and an outer surface of the first thermal conductive layer 314 may also be flat or planar. Surfaces of the first non-conductive layer 312 that are in contact with the first thermal conductive layer 314 may be flat or planar match the shape of side surfaces of the first thermal conductive layer 314.

According to other embodiments, as illustrated in FIG. 6, a second non-conductive layer 322 may have flat side surfaces. For example, outer side surfaces of the second non-conductive layer 322 may be perpendicular to the upper surface of the lower semiconductor chip 210. The outer side surfaces of the second non-conductive layer 322 may be vertically aligned with, and co-planar with, the side surfaces of the lower semiconductor chip 210 and the side surfaces of the upper semiconductor chip 220.

A first non-conductive layer 312 may have flat side surfaces. For example, outer side surfaces of the first non-conductive layer 312 may be perpendicular to the lower surface of the lower semiconductor chip 210. The outer side surfaces of the first non-conductive layer 312 may be vertically aligned with, and co-planar with, the side surfaces of the lower semiconductor chip 210.

According to other embodiments, unlike the embodiments of FIGS. 5 and 6, the first thermal conductive layer 314 and the second thermal conductive layer 324 may have convex side surfaces, and the first non-conductive layer 312 and the second non-conductive layer 322 may have flat side surfaces.

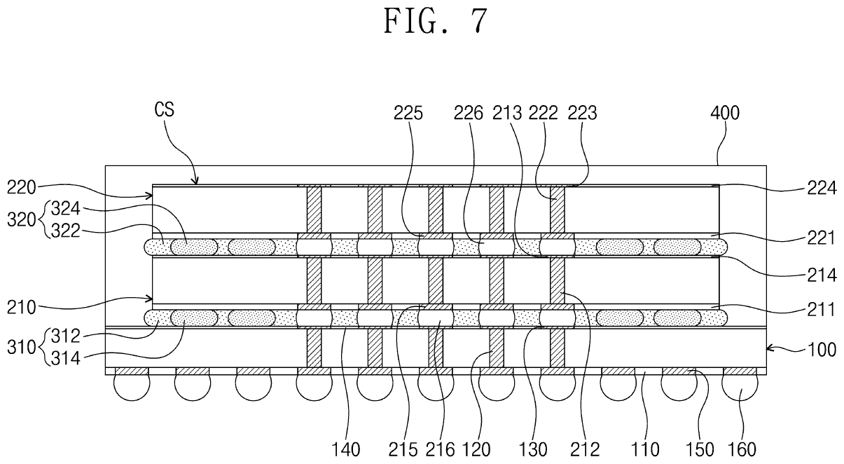

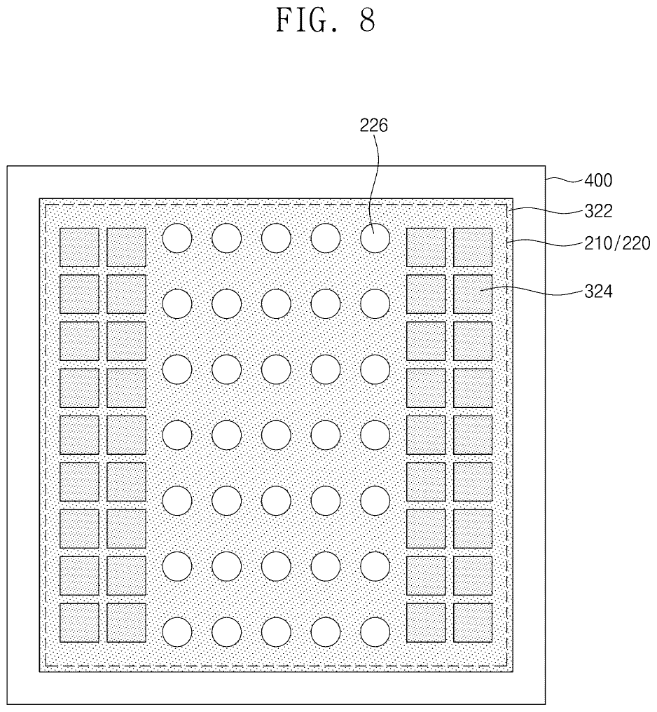

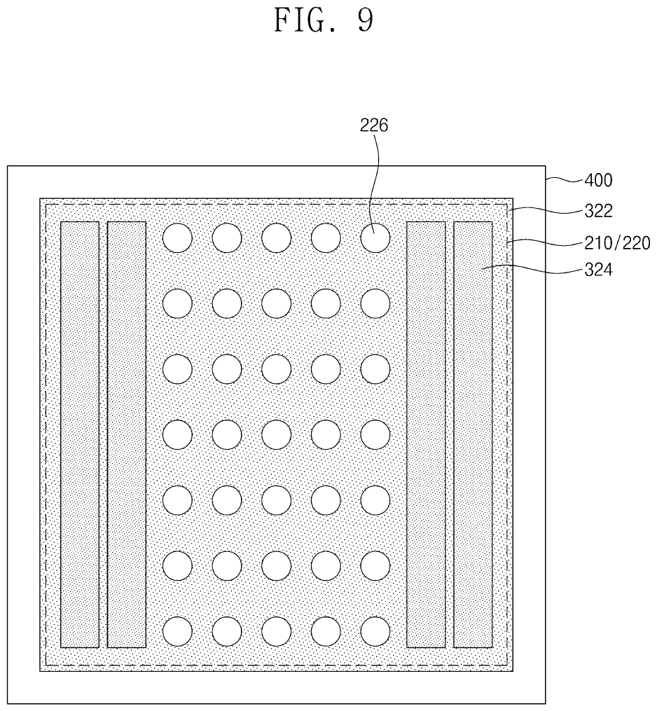

FIG. 7 is a cross-sectional view illustrating a semiconductor package according to embodiments of the inventive concept. FIGS. 8 and 9 are plan views illustrating a semiconductor package according to embodiments of the inventive concept.

As illustrated in FIGS. 1 to 6, the second thermal conductive layer 324 may be provided between a central region of the lower semiconductor chip 210 where a second chip connection terminals 226 are provided and one of the side surfaces of the lower semiconductor chip 210, but the inventive concept is not limited thereto.

Referring to FIGS. 7 and 8, a plurality of second thermal conductive layers 324 may be provided between the lower semiconductor chip 210 and the upper semiconductor chip 220, between the central region of the lower semiconductor chip 210 and one of the side surfaces of the lower semiconductor chip 210. A region disposed between the central region of the lower semiconductor chip 210 and one of the side surfaces of the lower semiconductor chip 210 may be defined as one edge region. A plurality of second thermal conductive layers 324 may be provided in the one edge region. While FIG. 7 illustrates two, separate, thermal conductive patterns (e.g., the separate thermal conductive patterns may, together, form the second thermal conductive layers 324) spaced apart from one another and provided in the one edge region, more than two thermal conductive patterns (e.g., that, together, form a second thermal conductive layer 324 at one vertical level) may be provided in the one edge region. As illustrated in FIG. 8, the second thermal conductive layers 324 may be disposed in the edge region to form a plurality of rows and a plurality of columns. For example, thermal conductive layers 324 may be positioned in the edge region to form a plurality of rows and a plurality of columns. As such, the second thermal conductive layers 324 may be disposed to form a grid shape in the edge region. Alternatively, the second thermal conductive layers 324 may be disposed in a honeycomb shape in the edge region, in which the second thermal conductive layers 324 may be arranged to form a hexagonal shape. A space between the second thermal conductive layers 324 may be filled by the second non-conductive layer 322. The second thermal conductive layers 324 may be arranged in various shapes, such as a square, a circle, or a polygon, when viewed in a plan view.

According to other embodiments, as illustrated in FIG. 9, the second thermal conductive layers 324 may have a line shape and may be elongated and extend linearly, wherein a length of the second thermal conductive layers 324 is greater than a width (e.g., the length is at least double the width, or the length is at least triple the width, or the length is at least quadruple the width). In the edge region, the second thermal conductive layers 324 may be disposed to include one or more rows and a plurality of columns. In FIG. 9, the second thermal conductive layers 324 are illustrated as extending along an adjacent side surface of the lower semiconductor chip 210 and may extend inwardly from the side surface toward the second chip connection terminals 226, but the inventive concept is not limited thereto. According to other embodiments, the second thermal conductive layers 324 may extend in the direction from the adjacent side surface of the lower semiconductor chip 210 toward the second chip connection terminals 226 and disposed along the side surface.

Between the base semiconductor chip 100 and the lower semiconductor chip 210, a plurality of first thermal conductive layers 314 may be provided between the central region of the lower semiconductor chip 210 and one of the side surfaces of the lower semiconductor chip 210. A plurality of first thermal conductive layers 314 may be provided in one edge region between the central region of the lower semiconductor chip 210 and one of the side surfaces of the lower semiconductor chip 210. Similar to the arrangement of the thermal conductive layers 324 in FIG. 8, in the edge region, the first thermal conductive layers 314 may be disposed to include a plurality of rows and a plurality of columns. For example, the first thermal conductive layers 314 may be disposed to form a grid shape in the edge region. Alternatively, the first thermal conductive layers 314 may be disposed in a honeycomb shape in the edge region, in which the second thermal conductive layers 324 may be arranged to form a hexagonal shape. A space between the first thermal conductive layers 314 may be filled by the first non-conductive layer 312. The first thermal conductive layers 314 may be arranged in various shapes such as a square, a circle, or a polygon, when viewed in a plan view.

According to other embodiments, the first thermal conductive layers 314 may have a line shape and may be elongated and extend linearly, wherein a length of the thermal conductive layers 314 is greater than a width (e.g., the length is at least double the width, or the length is at least triple the width, or the length is at least quadruple the width). Similar to the arrangement of FIG. 9, the first thermal conductive layers 314 may be disposed to have one or more rows and a plurality of columns in the edge region. The first thermal conductive layers 314 may extend along the adjacent side surface of the lower semiconductor chip 210 and may extend inwardly from the side surface toward the first chip connection terminals 216. According to other embodiments, the first thermal conductive layers 314 may extend in the direction from the adjacent side surface of the lower semiconductor chip 210 toward the first chip connection terminals 216 and may be disposed along the side surface.

According to embodiments of the inventive concept, the first thermal conductive layers 314 and the second thermal conductive layers 324 may be disposed on the edge region to avoid the first thermal conductive layers 314 from contacting the first chip connection terminals 216, and to avoid the second thermal conductive layers 324 from contacting the second chip connection terminals 226. In addition, the first non-conductive layer 312 may be filled between the first thermal conductive layers 314, and the second non-conductive layer 322 may be filled between the second thermal conductive layers 324. Accordingly, the size of the first non-conductive layer 312 and the second non-conductive layer 322 may be reduced to provide additional space for the thermal conductive layers, and the base semiconductor chip 100 and the lower semiconductor chip 210 and the lower semiconductor chip 210 and the upper semiconductor chip 220 may be firmly bonded. That is, a semiconductor package having high heat dissipation efficiency and improved structural stability may be provided.

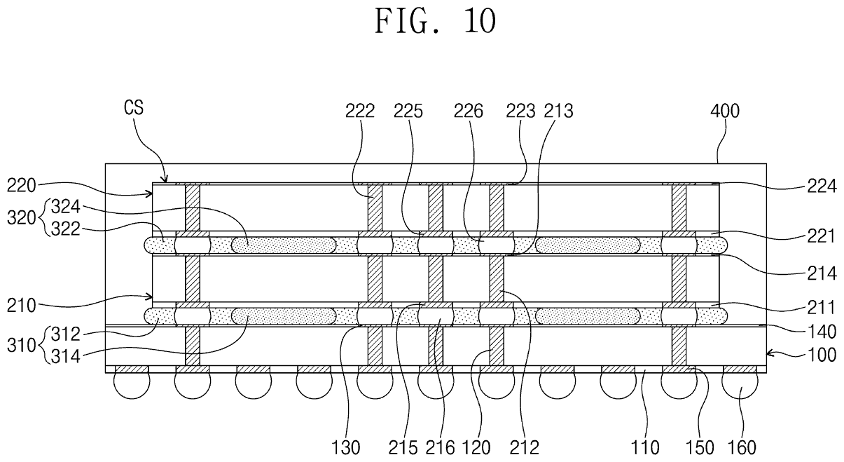

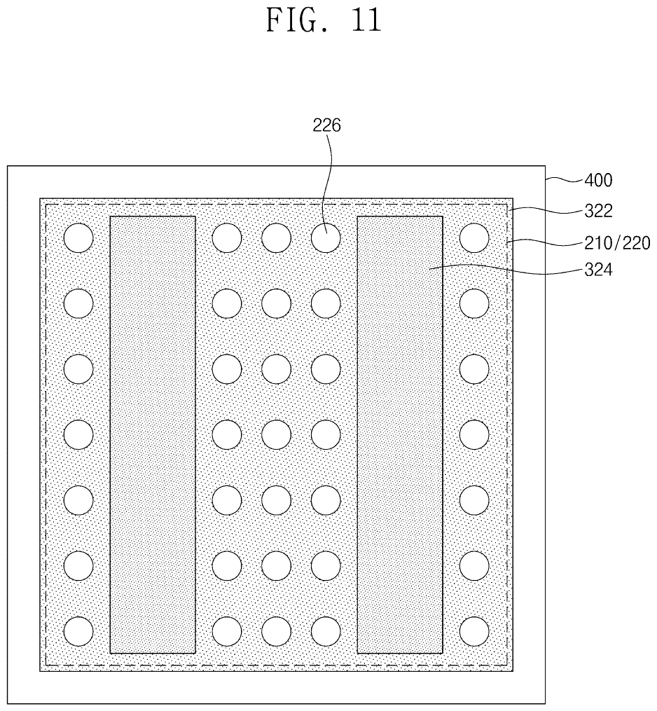

FIG. 10 is a cross-sectional view illustrating a semiconductor package according to embodiments of the inventive concept. FIG. 11 is a plan view illustrating a semiconductor package according to embodiments of the inventive concept.

With reference to FIGS. 10 and 11, at least some of the second chip connection terminals 226 may be disposed between the second thermal conductive layer 324 and the side surfaces of the lower semiconductor chip 210. The second thermal conductive layer 324 may be disposed between the second chip connection terminals 226, such that a line or axis passing between an outermost second chip connection terminal 226 (e.g., in proximity to side surfaces of the semiconductor chips 210, 220) and a second chip connection terminal 226 within the central region may pass through the second thermal conductive layer 324 that is between the outermost second chip connection terminal 226 and the second chip connection terminal 226 within the central region. The second chip connection terminals 226 disposed on a central region of the lower semiconductor chip 210 may be signal terminals that transmit an operation signal of the lower semiconductor chip 210 or the upper semiconductor chip 220. The outermost second chip connection terminals 226 disposed between the second thermal conductive layer 324 and the side surfaces of the lower semiconductor chip 210 may be ground/power terminals that transmit a ground signal or a power signal of the lower semiconductor chip 210 or the upper semiconductor chip 220.

At least some of the first chip connection terminals 216 may be disposed between the first thermal conductive layer 314 and the side surfaces of the lower semiconductor chip 210. The first thermal conductive layer 314 may be disposed between the first chip connection terminals 216, such that a line or axis passing between an outermost first chip connection terminal 216 (e.g., in proximity to side surfaces of the semiconductor chips 210, 220) and a first chip connection terminal 216 within the central region may pass through the first thermal conductive layer 314 that is between the outermost first chip connection terminal 216 and the first chip connection terminal 216 within the central region. The first chip connection terminals 216 disposed on a central region of the lower semiconductor chip 210 may be signal terminals that transmit an operation signal of the lower semiconductor chip 210. The outermost first chip connection terminals 216 disposed between the first thermal conductive layer 314 and the side surfaces of the lower semiconductor chip 210 may be ground/power terminals that transmit a ground signal or a power signal of the lower semiconductor chip 210.

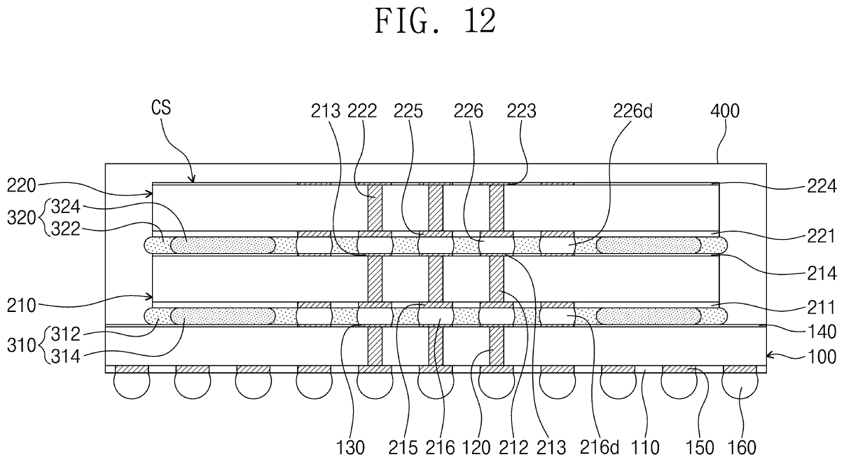

FIG. 12 is a cross-sectional view illustrating a semiconductor package according to embodiments of the inventive concept.

Referring to FIG. 12, at least some of the second chip connection terminals 226 may be second dummy terminals 226d. The second dummy terminals 226d may be disposed between the other second chip connection terminals 226 (e.g., that are not dummy terminals) and the second thermal conductive layer 324. That is, the second dummy terminals 226d may be adjacent to the second thermal conductive layer 324. The other second chip connection terminals 226 (e.g., that are not dummy terminals) may be spaced apart from the second thermal conductive layer 324 with the second dummy terminals 226d interposed therebetween. The second dummy terminals 226d may be electrically insulated from the integrated circuit in the upper semiconductor chip 220. For example, as illustrated in FIG. 12, the second dummy terminals 226d may not be electrically connected to the third vias 222 of the upper semiconductor chip 220.

At least some of the first chip connection terminals 216 may be first dummy terminals 216d. The first dummy terminals 216d may be disposed between the other first chip connection terminals 216 (e.g., that are not dummy terminals) and the first thermal conductive layer 314. That is, the first dummy terminals 216d may be adjacent to the first thermal conductive layer 314. The other first chip connection terminals 216 (e.g., that are not dummy terminals) may be spaced apart from the first thermal conductive layer 314 with the first dummy terminals 216d interposed therebetween. The first dummy terminals 216d may be electrically insulated from the integrated circuit in the lower semiconductor chip 210. For example, as illustrated in FIG. 12, the first dummy terminals 216d may not be electrically connected to the second vias 212 of the lower semiconductor chip 210.

According to embodiments of the inventive concept, the first dummy terminals 216d may be provided between the first chip connection terminals 216 transmitting the operation signal and the first thermal conductive layer 314, and the second dummy terminals 226d may be provided between the second chip connection terminals 226 transmitting the operation signal and the second thermal conductive layer 324. Accordingly, the first chip connection terminals 216 may be limited or prevented from being electrically short-circuited by the first thermal conductive layer 314, and the second chip connection terminals 226 may be limited from being electrically short-circuited by the second thermal conductive layer 324. That is, a semiconductor package with improved driving stability may be provided.

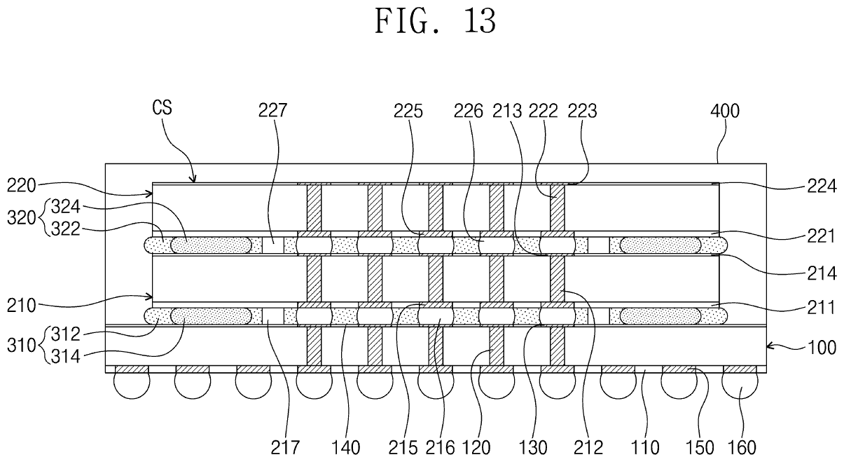

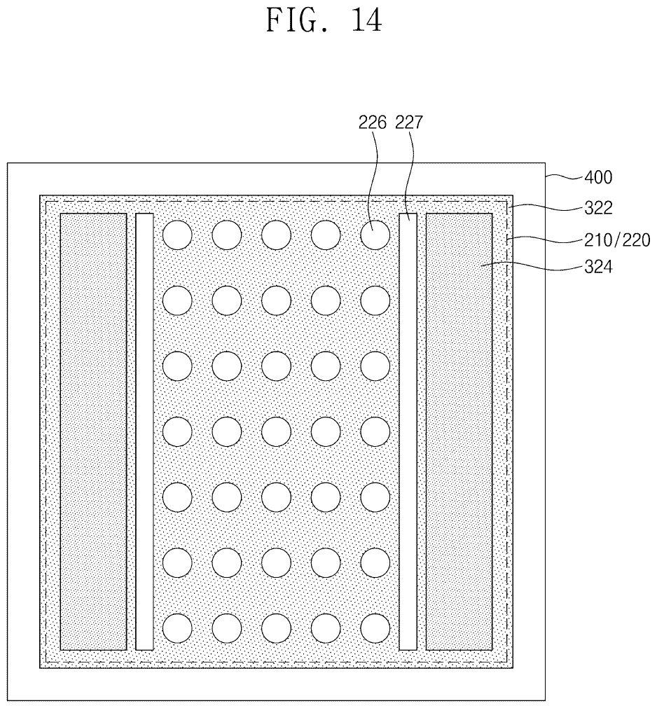

FIG. 13 is a cross-sectional view illustrating a semiconductor package according to embodiments of the inventive concept. FIG. 14 is a plan view illustrating a semiconductor package according to embodiments of the inventive concept.

Referring to FIGS. 13 and 14, the second adhesive layer 320 may further include a second dam structure 227. The second dam structure 227 may be disposed vertically between the upper semiconductor chip 220 and the lower semiconductor chip 210. The second dam structure 227 may be in contact with the upper surface of the lower semiconductor chip 210 and the lower surface of the upper semiconductor chip 220. The second dam structure 227 may be disposed horizontally between the second chip connection terminals 226 and the second thermal conductive layer 324. As illustrated in FIG. 14, the second dam structure 227 may have a line shape (e.g., elongated, linearly extending shape with a length that is greater than a width) extending between the second chip connection terminals 226 and the second thermal conductive layer 324, when viewed in a plan view. The second dam structure 227 may include an insulating material. The second dam structure 227 may include, for example, a silicon (Si) block or an insulating polymer. In some embodiments, the second dam structure 227 may comprise a height that is equal to a height of the second thermal conductive layer 324, and a height of the second non-conductive layer 322.

The first adhesive layer 310 may further include a first dam structure 217. The first dam structure 217 may be disposed vertically between the lower semiconductor chip 210 and the base semiconductor chip 100. The first dam structure 217 may be in contact with the upper surface of the base semiconductor chip 100 and the lower surface of the lower semiconductor chip 210. The first dam structure 217 may be disposed horizontally between the first chip connection terminals 216 and the first thermal conductive layer 314. Similar to the second dam structure 227 of FIG. 14, the first dam structure 217 may have a line shape (e.g., elongated, linearly extending shape with a length that is greater than a width) extending between the first chip connection terminals 216 and the first thermal conductive layer 314, when viewed in a plan view. The first dam structure 217 may include an insulating material. The first dam structure 217 may include, for example, a silicon (Si) block or an insulating polymer. In some embodiments, the first dam structure 217 may comprise a height that is equal to a height of the first thermal conductive layer 314, and a height of the first non-conductive layer 312.

According to embodiments of the inventive concept, the first dam structure 217 may be provided between the first chip connection terminals 216 and the first thermal conductive layer 314, and the second dam structure 227 may be provided between the second chip connection terminals 226 and the second thermal conductive layer 324. In some embodiments, and as illustrated in FIG. 13, the first dam structure 217 may overlap the second dam structure 227, for example, by being vertically aligned with one another. The first chip connection terminals 216 may be limited from being electrically short-circuited by the first thermal conductive layer 314 due to the first dam structure 217, and the second chip connection terminals 226 may be limited from being electrically short-circuited by the second thermal conductive layer 324 due to the second dam structure 227. That is, a semiconductor package with improved driving stability may be provided.

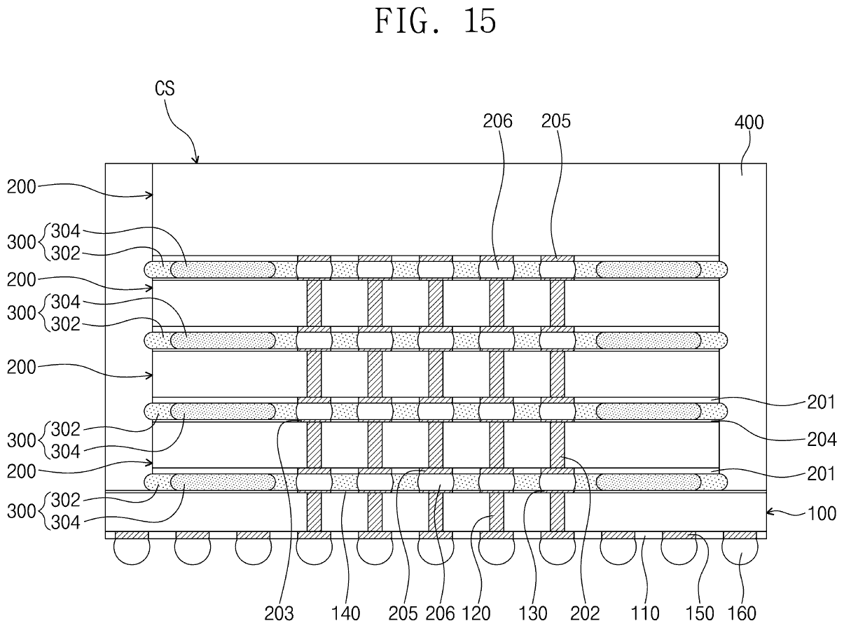

FIG. 15 is a cross-sectional view illustrating a semiconductor package according to embodiments of the inventive concept.

In FIGS. 1 to 14, two semiconductor chips 210 and 220 are stacked on a base semiconductor chip 100, but the inventive concept is not limited thereto.

Referring to FIG. 15, a chip stack CS may be provided on a base semiconductor chip 100. For example, a plurality of first semiconductor chips 200 may be stacked on the base semiconductor chip 100. Each of the first semiconductor chips 200 may be substantially identical to or similar to the lower semiconductor chip 210 or the upper semiconductor chip 220 described with reference to FIGS. 1 to 14. For example, each of the first semiconductor chips 200 may include a fourth circuit layer 201 facing the base semiconductor chip 100, a fourth protective layer 204 provided on an upper surface facing the fourth circuit layer 201, fourth vias 202 vertically penetrating the first semiconductor chips 200 and connected to the fourth circuit layer 201, fourth backside pads 203 electrically connected to the fourth vias 202 in the fourth protective layer 204, and fourth frontside pads 205 exposed on a lower surface of the fourth circuit layer 201 and electrically connected to the fourth vias 202. The first semiconductor chip 200 disposed at the uppermost end of the chip stack CS is the uppermost semiconductor chip and may not include the fourth protective layer 204, the fourth vias 202, and the fourth backside pads 203.

The first semiconductor chips 200 may be mounted on the base semiconductor chip 100 or the first semiconductor chip 200 disposed below by being electrically connected to third chip connection terminals 206. With reference to the lowermost semiconductor chip 200, the third chip connection terminals 206 may electrically connect the first backside pads 130 of the base semiconductor chip 100 and the fourth frontside pads 205 of the lowermost first semiconductor chip 200 disposed at the lowest position. For semiconductor chips 200 at a higher level, the third chip connection terminals 206 may connect the fourth backside pads 203 of one of the first semiconductor chips 200 and the fourth frontside pads 205 of another of the first semiconductor chips 200 disposed thereon.

Adhesive layers 300 may be provided between the base semiconductor chip 100 and the lowermost first semiconductor chip 200 disposed at the lowest position, and between the first semiconductor chips 200 adjacent to, and stacked on top of, each other. The adhesive layers 300 may be identical to or similar to the first adhesive layer 310 and the second adhesive layer 320 described with reference to FIGS. 1 to 14. For example, each of the adhesive layers 300 may include at least one thermal conductive layer 302 disposed horizontally spaced from the third chip connection terminals 206, and a non-conductive layer 304 surrounding the thermal conductive layer 302 and the third chip connection terminals 206.

A molding layer 400 may be provided on the base semiconductor chip 100. The molding layer 400 may cover at least a portion of an upper surface of the base semiconductor chip 100. Side surfaces of the molding layer 400 may be aligned with side surfaces of the base semiconductor chip 100. The molding layer 400 may surround the chip stack CS. That is, the molding layer 400 may cover the side surfaces of the first semiconductor chips 200. The molding layer 400 may expose the upper surface of the uppermost first semiconductor chip 200. The molding layer 400 may also cover the side surfaces of the adhesive layers 300 that are exposed at edge regions of the semiconductor chips 200.

FIG. 16 is a cross-sectional view illustrating a semiconductor module according to embodiments of the inventive concept.

Referring to FIG. 16, a semiconductor module may be, for example, a memory module including a module substrate 910, a chip stack package 10 and a second semiconductor chip 940 mounted on the module substrate 910, and an external molding layer 950 covering the chip stack package 10 and the second semiconductor chip 940. The semiconductor module may further include an interposer 920 provided on the module substrate 910.

The module substrate 910 may be provided. The module substrate 910 may include a printed circuit board (PCB) having a signal pattern on an upper surface thereof.

Module terminals 912 may be disposed below the module substrate 910. The module substrate 910 may include solder balls or solder bumps, and the semiconductor module may be provided in the form of a ball grid array (BGA), a fine ball-grid array (FBGA), or a land grid array (LGA) depending on the type and arrangement of the module substrate 910.

The interposer 920 may be provided on the module substrate 910. The interposer 920 may include first substrate pads 922 exposed on an upper surface of the interposer 920, and second substrate pads 924 exposed on a lower surface of the interposer 920. The interposer 920 may redistribute the chip stack package 10 and the second semiconductor chip 940. The interposer 920 may be mounted on the module substrate 910 in a flip chip manner. For example, the interposer 920 may be mounted on the module substrate 910 using substrate terminals 926 provided on, and electrically connected with, the second substrate pads 924. The substrate terminals 926 may include solder balls or solder bumps, etc. A first underfill layer 928 may be provided between the module substrate 910 and the interposer 920.

The chip stack package 10 may be disposed on the interposer 920. The chip stack package 10 may have a structure identical to or similar to the semiconductor package described with reference to FIG. 15. Although FIG. 16 illustrates the semiconductor package of FIG. 15 as a reference, the chip stack package 10 may have a structure identical to or similar to any of the semiconductor packages described with reference to FIGS. 1 to 14.

The chip stack package 10 may be mounted on the interposer 920. For example, the chip stack package 10 may be electrically connected to the first substrate pads 922 of the interposer 920 through the external terminals 160 of the base semiconductor chip 100. A second underfill layer 932 may be provided between the chip stack package 10 and the interposer 920. The second underfill layer 932 may fill a space between the interposer 920 and the base semiconductor chip 100 and surround the external terminals 160 of the base semiconductor chip 100.

The second semiconductor chip 940 may be disposed on the interposer 920. The second semiconductor chip 940 may be disposed spaced apart from the chip stack package 10, for example, by being spaced apart in a horizontal direction. A thickness of the second semiconductor chip 940 may be greater than a thickness of the base semiconductor chip 100 of the chip stack package 10, and the thickness of the second semiconductor chip 940 may be greater than a thickness of each of the first semiconductor chips 200. The second semiconductor chip 940 may include a graphic processing unit (GPU). The second semiconductor chip 940 may include a logic circuit. That is, the second semiconductor chip 940 may be a logic chip. Bumps 942 may be provided on a lower surface of the second semiconductor chip 940. For example, the second semiconductor chip 940 may be electrically connected to first substrate pads 922 of the interposer 920 through the bumps 942. A third underfill layer 944 may be provided between the interposer 920 and the second semiconductor chip 940. The third underfill layer 944 may fill a space between the interposer 920 and the second semiconductor chip 940 and surround the bumps 942.

An outer molding layer 950 may be provided on the interposer 920. The outer molding layer 950 may cover at least a portion of an upper surface of the interposer 920. The outer molding layer 950 may surround the chip stack package 10 and the second semiconductor chip 940. An upper surface of the outer molding layer 950 may be disposed at a similar level as an upper surface of the chip stack package 10 (e.g., as illustrated in FIG. 16), or the upper surface of the outer molding layer 950 may be disposed at the same level as an upper surface of the chip stack package 10. The outer molding layer 950 may include an insulating material. For example, the outer molding layer 950 may include an epoxy molding compound (EMC).

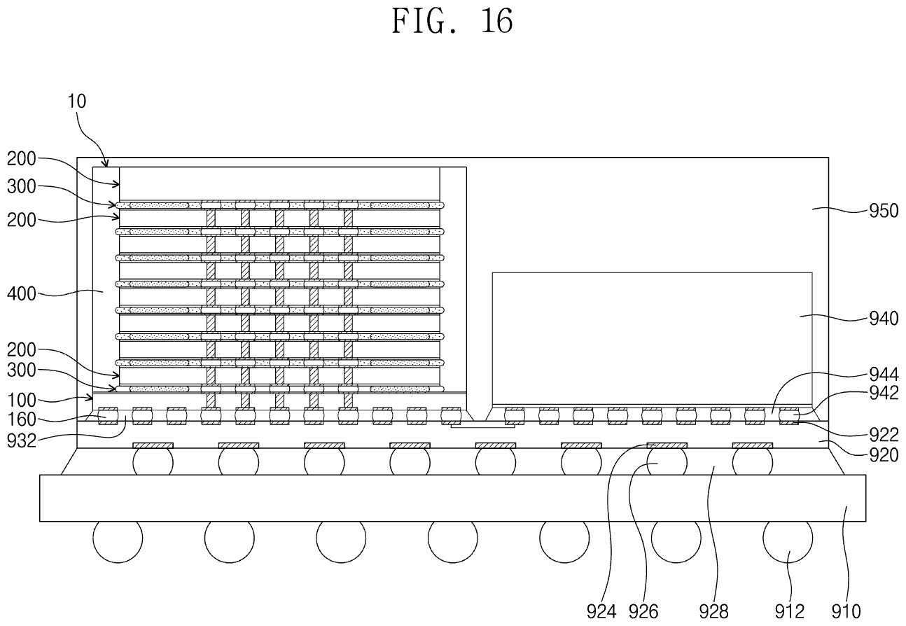

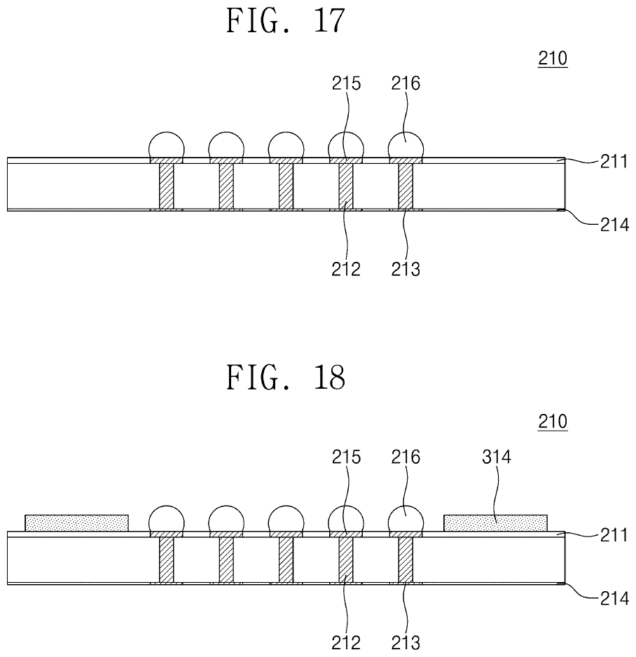

FIGS. 17 to 24 are cross-sectional views illustrating a method of manufacturing a semiconductor package according to embodiments of the inventive concept.

Referring to FIG. 17, a lower semiconductor chip 210 may be provided. The lower semiconductor chip 210 may be formed through a conventional process. The lower semiconductor chip 210 may have a configuration substantially the same as or similar to the lower semiconductor chip 210 described with reference to FIGS. 1 to 14. For example, the lower semiconductor chip 210 may include the second circuit layer 211 provided on the upper surface of the lower semiconductor chip 210, the second protective layer 214 provided on the lower surface facing the second circuit layer 211, second vias 212 vertically penetrating the lower semiconductor chip 210 and connected to the second circuit layer 211, second backside pads 213 connected to the second vias 212 in the second protective layer 214, and second frontside pads 215 exposed on the upper surface of the second circuit layer 211. The second frontside pads 215 may be disposed on the central region of the lower semiconductor chip 210.

The first chip connection terminals 216 may be provided on the lower semiconductor chip 210. The first chip connection terminals 216 may be attached to the second frontside pads 215.

Referring to FIG. 18, the first thermal conductive layer 314 may be formed on the lower semiconductor chip 210. The first thermal conductive layer 314 may be formed between the side surfaces of the lower semiconductor chip 210 and the first chip connection terminals 216. For example, forming the first thermal conductive layer 314 may include depositing or applying a material having high thermal conductivity and then patterning the material. Alternatively, the first thermal conductive layer 314 may be formed by painting a material having high thermal conductivity on the upper surface of the lower semiconductor chip 210. The first thermal conductive layer 314 may be disposed on the edge region of the lower semiconductor chip 210.

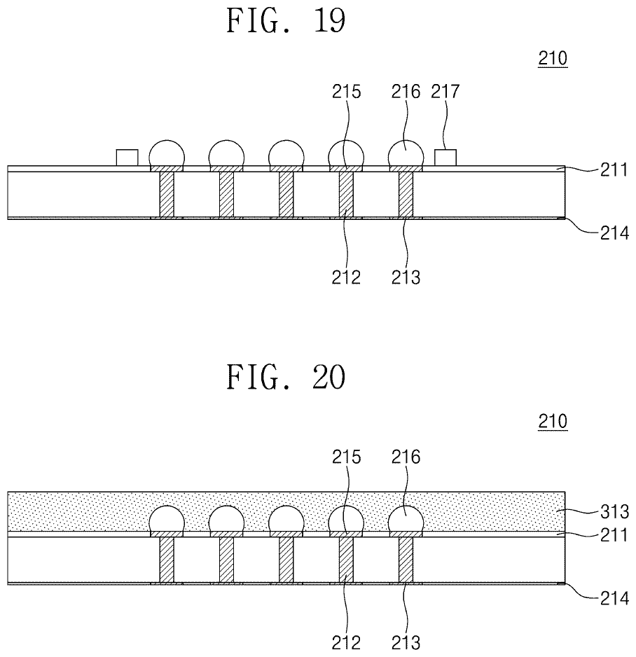

According to other embodiments, referring to FIG. 19, the first dam structure 217 (e.g., corresponding to FIG. 13) may be formed on the lower semiconductor chip 210. The first dam structure 217 may be formed between side surfaces of the lower semiconductor chip 210 and the first chip connection terminals 216. The first dam structure 217 may be positioning adjacent to the first chip connection terminals 216. For example, the first dam structure 217 may be formed by positioning a silicon block or a metal block on the lower semiconductor chip 210. The first dam structure 217 may be positioned on the edge region of the lower semiconductor chip 210. Hereinafter, the description will continue based on the result of FIG. 17.

FIG. 20 illustrates method steps following the structure formed in FIG. 17, wherein a preliminary non-conductive layer 313 may be formed on the lower semiconductor chip 210. For example, when the preliminary non-conductive layer 313 is a non-conductive adhesive, the preliminary non-conductive layer 313 may be formed by applying a liquid non-conductive adhesive on the lower semiconductor chip 210, for example, by dispensing the liquid non-conductive adhesive. When the preliminary non-conductive layer 313 is a non-conductive layer, the preliminary non-conductive layer 313 may be formed by attaching the non-conductive layer to the lower semiconductor chip 210. The preliminary non-conductive layer 313 may cover the first chip connection terminals 216 on an upper surface of the lower semiconductor chip 210.

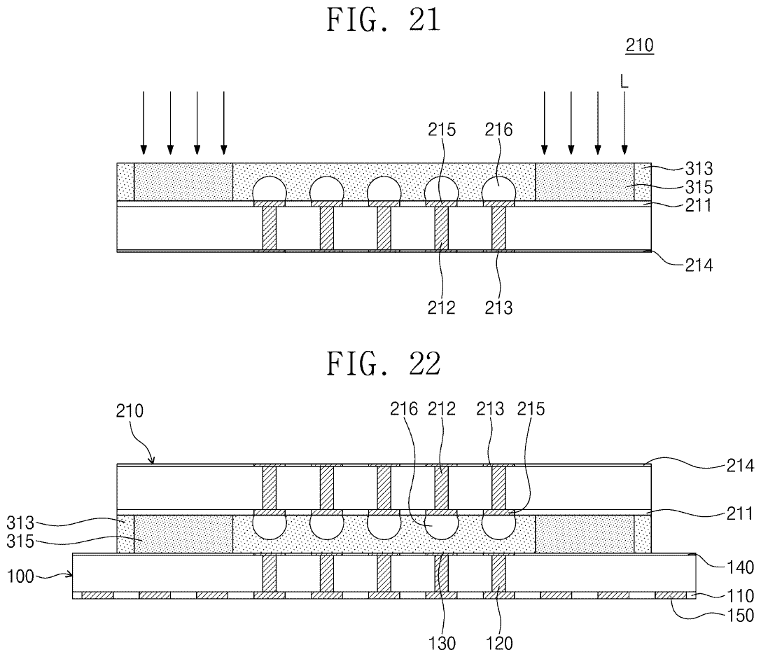

Referring to FIG. 21, a laser irradiation process may be performed on the preliminary non-conductive layer 313. For example, a preliminary thermal conductive layer 315 may be formed by irradiating a laser on the preliminary non-conductive layer 313. The preliminary thermal conductive layer 315 may be formed between the side surfaces of the lower semiconductor chip 210 and the first chip connection terminals 216. The preliminary thermal conductive layer 315 may be disposed on the edge region of the lower semiconductor chip 210. A laser L used in the laser irradiation process may be a CO₂ laser. By irradiating the preliminary non-conductive layer 313 with the laser L, a portion of the preliminary non-conductive layer 313 may be carbonized, thereby forming the preliminary thermal conductive layer 315 including laser induced graphene (LIG). According to other embodiments, the preliminary thermal conductive layer 315 may be formed by performing a chemical reduction process on the preliminary non-conductive layer 313. As such, the preliminary thermal conductive layer 315 may be formed from the preliminary non-conductive layer 313, for example, with the preliminary non-conductive layer 313 initially comprising the same, uniform thermal conductivity throughout the preliminary non-conductive layer 313, but after a portion of the preliminary non-conductive layer 313 is treated (e.g., by the laser L in the laser irradiation process or by the chemical reduction process), the treated portion of the preliminary non-conductive layer 313 forms the preliminary thermal conductive layer 315 and may comprise a higher thermal conductivity, while the untreated preliminary non-conductive layer 313 may have a lower thermal conductivity.

According to other embodiments, a compression process may be performed on the preliminary thermal conductive layer 315. For example, the preliminary thermal conductive layer 315 may be pressed toward the lower semiconductor chip 210, for example, by applying a force to an upper surface of the preliminary thermal conductive layer 315 with the force applied in a direction toward the lower surface of the preliminary thermal conductive layer 315. A density of the preliminary thermal conductive layer 315 may increase by the pressing process. When the preliminary thermal conductive layer 315 includes graphene, the thermal conductivity may increase as the density increases due to the pressing process. That is, a thermal conductivity of the preliminary thermal conductive layer 315 after the pressing process may be greater than a thermal conductivity of the preliminary thermal conductive layer 315 before the pressing process.

Referring to FIG. 22, a base semiconductor chip 100 may be provided. The base semiconductor chip 100 may include a configuration substantially the same as or similar to the base semiconductor chip 100 described with reference to FIGS. 1 to 14. For example, the base semiconductor chip 100 may include the first circuit layer 110 provided on the lower surface of the base semiconductor chip 100, the first protective layer 140 provided on an upper surface facing the first circuit layer 110, first vias 120 vertically penetrating the base semiconductor chip 100 and connected to the first circuit layer 110, first backside pads 130 connected to the first vias 120 in the first protective layer 140, and first frontside pads 150 exposed on the lower surface of the first circuit layer 110.

The lower semiconductor chip 210 may be provided on the base semiconductor chip 100. The lower semiconductor chip 210 may be disposed such that the preliminary non-conductive layer 313 and the preliminary thermal conductive layer 315 face the base semiconductor chip 100. The first chip connection terminals 216 of the lower semiconductor chip 210 may be aligned with the first backside pads 130 of the base semiconductor chip 100. The preliminary non-conductive layer 313 and the preliminary thermal conductive layer 315 may be in contact with the upper surface of the base semiconductor chip 100.

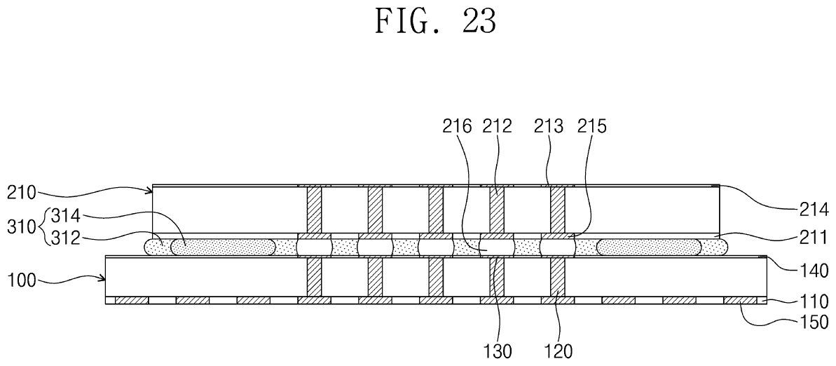

Referring to FIG. 23, the lower semiconductor chip 210 may be bonded to the base semiconductor chip 100 through thermocompression bonding. The first chip connection terminals 216 may electrically connect the lower semiconductor chip 210 and the base semiconductor chip 100. For example, when the lower semiconductor chip 210 is pressed in a direction toward the base semiconductor chip 100, the preliminary non-conductive layer 313 and the preliminary thermal conductive layer 315 may be pressed to form the first non-conductive layer 312 and the first thermal conductive layer 314. By the thermal compression process, side surfaces of the first thermal conductive layer 314 may protrude toward the first non-conductive layer 312, such that the side surfaces of the first thermal conductive layer 314 may form the convex shape. By the thermal compression process, side surfaces of the first non-conductive layer 312 may protrude outside the side surfaces of the lower semiconductor chip 210, such that the side surfaces of the first non-conductive layer 312 may form the convex shape. The first non-conductive layer 312 may be hardened by the thermal compression process.

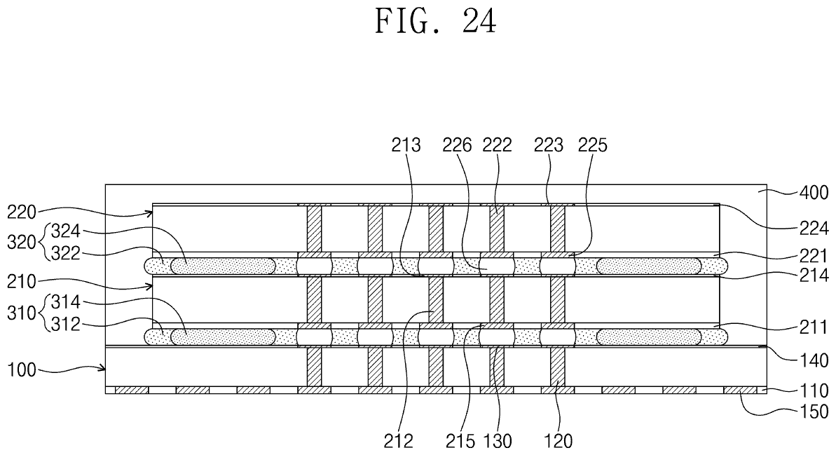

Referring to FIG. 24, the upper semiconductor chip 220 may be provided. The upper semiconductor chip 220 may include a configuration substantially identical or similar to the upper semiconductor chip 220 described with reference to FIGS. 1 to 14. For example, the upper semiconductor chip 220 may include the third circuit layer 221 provided on the lower surface of the upper semiconductor chip 220, the third protective layer 224 provided on the upper surface facing the third circuit layer 221, third vias 222 vertically penetrating the upper semiconductor chip 220 and connected to the third circuit layer 221, third backside pads 223 connected to the third vias 222 in the third protective layer 224, and third frontside pads 225 exposed on an upper surface of the third circuit layer 221.

Second chip connection terminals 226 may be provided on the upper semiconductor chip 220. The second chip connection terminals 226 may be attached to the third frontside pads 225.

A process of forming the second non-conductive layer 322 and the second thermal conductive layer 324 and mounting the upper semiconductor chip 220 on the lower semiconductor chip 210 may be substantially the same as the process of forming the first non-conductive layer 312 and the first thermal conductive layer 314 and mounting the lower semiconductor chip 210 on the base semiconductor chip 100. For example, a preliminary non-conductive layer covering the second chip connection terminals 226 may be formed on the upper semiconductor chip 220, a laser irradiation process may be performed on the preliminary non-conductive layer to form a preliminary thermal conductive layer, the upper semiconductor chip 220 may be moved to bring the preliminary non-conductive layer and the preliminary thermal conductive layer into contact with the upper surface of the lower semiconductor chip 210, and a thermocompression bonding process may be performed on the upper semiconductor chip 220 to mount the upper semiconductor chip 220 on the lower semiconductor chip 210, and at the same time, the second non-conductive layer 322 and the second thermal conductive layer 324 may be formed.

A molding material covering the lower semiconductor chip 210 and the upper semiconductor chip 220 may be applied or deposited on the base semiconductor chip 100, and then the molding material may be cured to form a molding layer 400.

Referring again to FIG. 1, external terminals 160 may be attached on the lower surface of the base semiconductor chip 100.

According to embodiments of the inventive concept, the semiconductor package may include the adhesive layer having the high thermal conductivity provided between the semiconductor chips. Accordingly, the heat generated from the semiconductor chips may be rapidly transferred in the vertical direction, and the heat may be easily discharged to the outside of the semiconductor package. That is, the semiconductor package with the high heat dissipation efficiency may be provided. In addition, the thermal conductive layer may be disposed spaced apart from the chip connection terminals, and thus the electrical short may not occur between the chip connection terminals. Furthermore, the non-conductive layer may be provided between the semiconductor chips. The non-conductive layer surrounding the thermal conductive layer may surround the thermal conductive layer so that the thermal conductive layer is not exposed. Furthermore, the non-conductive layer has a higher adhesive strength than an adhesive strength of the thermal conductive layer, such that the non-conductive layer may firmly bond the semiconductor chips to one another. That is, the semiconductor package with the improved structural stability may be provided.

While embodiments are described above, a person skilled in the art may understand that many modifications and variations are made without departing from the spirit and scope of the inventive concept. Accordingly, the example embodiments of the inventive concept should be considered in all respects as illustrative and not restrictive, with the spirit and scope of the invention being indicated by the appended claims.

What is claimed is:

1. A semiconductor package comprising:
a substrate including a plurality of vias passing therethrough;
a chip stack mounted on the substrate; and
a molding layer surrounding the chip stack on the substrate,
wherein the chip stack includes:
a first semiconductor chip on the substrate;
a second semiconductor chip on the first semiconductor chip;
connection terminals between the first semiconductor chip and the second semiconductor chip and electrically connecting the first semiconductor chip and the second semiconductor chip; and
an adhesive layer between the first semiconductor chip and the second semiconductor chip and surrounding the connection terminals,
wherein the adhesive layer includes:
a thermal conductive layer in contact with an upper surface of the first semiconductor chip and a lower surface of the second semiconductor chip, wherein the thermal conductive layer comprises a width that is greater than a height of the thermal conductive layer; and
a non-conductive layer surrounding the thermal conductive layer and surrounding the connection terminals,
wherein the thermal conductive layer is spaced apart from the connection terminals, and
wherein a thermal conductivity of the thermal conductive layer is greater than a thermal conductivity of the non-conductive layer.

2. The semiconductor package of claim 1, wherein the non-conductive layer surrounds the thermal conductive layer when viewed in a plan view, and
wherein the thermal conductive layer is spaced apart from side surfaces of the first semiconductor chip and side surfaces of the second semiconductor chip.

3. The semiconductor package of claim 1, wherein the thermal conductive layer includes graphene, metal, or diamond, and
wherein the non-conductive layer includes an insulating polymer.

4. The semiconductor package of claim 3, wherein the thermal conductive layer includes graphene,
wherein the thermal conductive layer further includes an impurity in the thermal conductive layer, and
wherein the impurity includes at least one material that forms the non-conductive layer.

5. The semiconductor package of claim 1, wherein a distance between the thermal conductive layer and a connection terminal of the connection terminals that is closest to the thermal conductive layer is between 1 micrometer to 20 micrometers.

6. The semiconductor package of claim 1, wherein the connection terminals are disposed on a central region of the first semiconductor chip, and
wherein the thermal conductive layer is disposed between the central region of the first semiconductor chip and a side surface of the first semiconductor chip.

7. The semiconductor package of claim 1, wherein thermal conductive layer is one of a plurality of thermal conductive layers,
and wherein the plurality of thermal conductive layers are arranged in a plurality of rows when viewed from a plan view.

8. The semiconductor package of claim 1, wherein the connection terminals are in contact with the non-conductive layer.

9. The semiconductor package of claim 1, wherein the chip stack further includes a dam structure between the first semiconductor chip and the second semiconductor chip in a vertical first direction, and between the connection terminals and the thermal conductive layer in a horizontal second direction, and
wherein the dam structure includes an insulating material.

10. The semiconductor package of claim 9, wherein the dam structure has an elongated line shape comprising a length that is greater than a width when viewed in a plan view.

11. The semiconductor package of claim 1, wherein the thermal conductive layer has convex side surfaces that extend outwardly toward the non-conductive layer.

12. The semiconductor package of claim 1, wherein a height of the thermal conductive layer is equal to a height of the non-conductive layer, and the thermal conductive layer is a single, unitary body.

13. A semiconductor package comprising:
an interposer substrate; and
a chip stack on the interposer substrate,
wherein the chip stack includes:
a first semiconductor chip;
a second semiconductor chip on the first semiconductor chip;
connection terminals between the first semiconductor chip and the second semiconductor chip and electrically connecting the first semiconductor chip and the second semiconductor chip; and
a thermal conductive layer between the first semiconductor chip and the second semiconductor chip,
wherein the thermal conductive layer is horizontally spaced apart from the connection terminals, and
wherein the thermal conductive layer includes carbon (C).

14. The semiconductor package of claim 13, further comprising:
a package substrate, wherein the interposer substrate is on the package substrate; and
a third semiconductor chip on the interposer substrate and horizontally spaced apart from the chip stack;
wherein the chip stack further includes a non-conductive layer filling a space between the first semiconductor chip and the second semiconductor chip and surrounding the connection terminals and the thermal conductive layer, and
wherein a thermal conductivity of the thermal conductive layer is greater than a thermal conductivity of the non-conductive layer.

15. The semiconductor package of claim 14, wherein the thermal conductive layer includes graphene,
wherein the non-conductive layer includes an insulating polymer,
wherein the thermal conductive layer further includes an impurity in the thermal conductive layer, and
wherein the impurity includes at least one material that forms the non-conductive layer.

16. The semiconductor package of claim 14, wherein the non-conductive layer surrounds the thermal conductive layer when viewed in a plan view, and
wherein the thermal conductive layer is spaced apart from side surfaces of the first semiconductor chip and the second semiconductor chip.

17. The semiconductor package of claim 13, wherein the thermal conductive layer is in contact with the first semiconductor chip and the second semiconductor chip.

18. A method of manufacturing a semiconductor package, the method comprising:
providing a first semiconductor chip having a central region and an edge region surrounding the central region, the first semiconductor chip including chip pads on a first surface of the first semiconductor chip on the central region;
electrically connecting connection terminals to the chip pads on the first surface of the first semiconductor chip;
applying a non-conductive layer surrounding the connection terminals;
performing a laser irradiation process on the non-conductive layer to form a thermal conductive layer;
positioning a second semiconductor chip on the non-conductive layer and the thermal conductive layer; and
performing a thermocompression process on the second semiconductor chip to bond the first semiconductor chip and the second semiconductor chip,
wherein the thermal conductive layer includes laser induced graphene (LIG).

19. The method of claim 18, wherein the non-conductive layer includes carbon, and
wherein a laser used in the laser irradiation process includes a CO₂ laser.

20. The method of claim 18, further comprising compressing the thermal conductive layer after the formation of the thermal conductive layer,
wherein a thermal conductivity of the thermal conductive layer after the compression is greater than a thermal conductivity of the thermal conductive layer before the compression.

21. A semiconductor package comprising:
a substrate including a plurality of vias passing therethrough;
a chip stack mounted on the substrate; and
a molding layer surrounding the chip stack on the substrate,
wherein the chip stack includes:
a first semiconductor chip on the substrate;
a second semiconductor chip on the first semiconductor chip;
connection terminals between the first semiconductor chip and the second semiconductor chip and electrically connecting the first semiconductor chip and the second semiconductor chip; and
an adhesive layer between the first semiconductor chip and the second semiconductor chip and surrounding the connection terminals,
wherein the adhesive layer includes:
a thermal conductive layer in contact with an upper surface of the first semiconductor chip and a lower surface of the second semiconductor chip, the thermal conductive layer spaced apart from the connection terminals; and
a non-conductive layer surrounding the thermal conductive layer and surrounding the connection terminals, wherein a thermal conductivity of the thermal conductive layer is at least 40 times greater than a thermal conductivity of the non-conductive layer.

22. The semiconductor package of claim 21, wherein a height of the thermal conductive layer is equal to a height of the non-conductive layer.

23. The semiconductor package of claim 21, wherein a distance separates the connection terminals from a side surface of the first semiconductor chip, and wherein a width of the thermal conductive layer between the connection terminals and the side surface is greater than 50% of the distance.
